(19) United States
(12) Patent Application Publication
(10) Pub. No.: US 2024/0333233 A1
(43) Pub. Date: Oct. 3, 2024

(54) ELECTRONIC DEVICE FOR PREVENTING OR REDUCING POWER AMPLIFIER DAMAGE AND METHOD FOR OPERATING THEREOF

(71) Applicant: Samsung Electronics Co., Ltd., Suwon-si (KR)

(72) Inventors: Hyunsang KANG, Suwon-si (KR); Juho VAN, Suwon-si (KR); Yongjun AN, Suwon-si (KR); Hyoseok NA, Suwon-si (KR); Yohan MOON, Suwon-si (KR)

(21) Appl. No.: 18/621,885

(22) Filed: Mar. 29, 2024

Related U.S. Application Data
(63) Continuation of application No. PCT/KR2024/003957, filed on Mar. 28, 2024.

(30) Foreign Application Priority Data
Mar. 30, 2023 (KR) 10-2023-0042335

(51) Int. Cl. H03F 1/52; H03F 1/02; H03F 3/24; H04B 1/04

(52) U.S. Cl. CPC H03F 1/52; H03F 1/0227; H03F 3/24; H04B 1/04; H03F 2200/336; H03F 2200/451; H04B 2001/0408

(57) ABSTRACT

According to an embodiment, an electronic device may include: a first modulator, a second modulator, a first power amplifier (PA) electrically connected to the first modulator and the second modulator through a switch, and at least one processor, comprising processing circuitry, operatively connected to the first PA, the first modulator, and the second modulator, wherein the instructions, when executed by at least one processor, individually and/or collectively, may cause the electronic device to: activate the first modulator and the second modulator, based on identifying a first event associated with satellite communication, supply power of a first voltage or higher to the first PA, based on controlling at least one switch among a plurality of switches included in each of the activated first modulator and second modulator, and activate a ground switch connected to a ground included in any one modulator of the first modulator or the second modulator, based on a first period, based on a first signal associated with the satellite communication being input to the first PA supplied with the power.

### CROSS-REFERENCE TO RELATED APPLICATIONS

This application is a continuation of International Application No. PCT/KR2024/003957 designating the United States, filed on Mar. 28, 2024, in the Korean Intellectual Property Receiving Office and claiming priority to Korean Patent Application No. 10-2023-0042335, filed on Mar. 30, 2023, in the Korean Intellectual Property Office, the disclosures of each of which are incorporated by reference herein in their entireties.

### BACKGROUND

### Field

The disclosure relates to an electronic device for preventing and/or reducing damage to a power amplifier and a method for operating the same.

### Description of Related Art

Electronic devices that support non-terrestrial network communication (e.g., satellite communication) are being actively introduced. In one example, an electronic device may communicate with a satellite of an existing satellite communication service provider using a frequency and a communication method of the service provider. In one example, an electronic device may communicate with a satellite using a cellular frequency according to a long-term evolution (LTE) standard, based on the LTE standard (or 5G standard). In one example, an electronic device may communicate with a satellite, based on a 5G non-terrestrial networks (NTN) standard.

For example, when an electronic device communicates with a non-terrestrial network, based on the LTE standard, some of frequencies defined in the LTE standard may be allocated for non-terrestrial communication. The electronic device may perform satellite communication using a protocol stack used in terrestrial communication, and an additional protocol stack for the non-terrestrial communication may not be required.

To transmit a signal from an electronic device to a communication network (e.g., a base station), data generated from a processor or a communication processor may be processed via a radio-frequency integrated circuit (RFIC) and a radio-frequency front-end (RFFE) circuit in the electronic device and may then be transmitted to the outside of the electronic device through at least one antenna. At least one antenna may be included in the electronic device to transmit signals in various frequency bands. The at least one antenna may be configured to support signals in a plurality of frequency bands, based on a multiplexer. The electronic device may determine, based on an allowed maximum transmission power, an output of a power amplifier in the RFFE circuit for stable communication at a cell edge.

### SUMMARY

According to an example embodiment, an electronic device may include: memory storing instructions, a first modulator, a second modulator, a first power amplifier (PA) electrically connected to the first modulator and the second modulator through a switch, and at least one processor, comprising processing circuitry, operatively connected to the first PA, the first modulator, and the second modulator. The instructions, when executed by at least one processor, individually and/or collectively, may cause the electronic device to: activate the first modulator and the second modulator, based on identifying a first event associated with satellite communication; supply power of a first voltage or higher to the first PA, based on controlling at least one switch among a plurality of switches included in each of the activated first modulator and second modulator; and activate a ground switch connected to a ground, included in any one modulator of the first modulator or the second modulator, based on a first period, based on a first signal associated with the satellite communication being input to the first PA supplied with the power.

According to an example embodiment, a non-transitory computer-readable storage medium may store at least one instruction, the at least one instruction may, when executed by at least one processor of an electronic device, individually and/or collectively, cause the electronic device to perform at least one operation including: activating a first modulator of the electronic device and a second modulator of the electronic device, based on identifying a first event associated with satellite communication; supplying power of a first voltage or higher to a first power amplifier (PA) of the electronic device electrically connected to the first modulator and the second modulator through a switch, based on controlling at least one switch among a plurality of switches included in each of the activated first modulator and second modulator; and activating a ground switch connected to a ground, included in any one modulator of the first modulator or the second modulator, based on a first period, based on a first signal associated with the satellite communication being input to the first PA supplied with the power.

According to an example embodiment, a method of operating an electronic device may include: activating a first modulator of the electronic device and a second modulator of the electronic device, based on identifying a first event associated with satellite communication; supplying power of a first voltage or higher to a first power amplifier (PA) of the electronic device electrically connected to the first modulator and the second modulator through a switch, based on controlling at least one switch among a plurality of switches included in each of the activated first modulator and second modulator; and activating a ground switch connected to a ground, included in any one modulator of the first modulator or the second modulator, based on a first period, based on a first signal associated with the satellite communication being input to the first PA supplied with the power.

According to an example embodiment, an electronic device may include: memory storing instructions, a first modulator, a second modulator, a first power amplifier (PA) electrically connected to the first modulator and the second modulator through a switch, and at least one processor, comprising processing circuitry, operatively connected to the first PA, the first modulator, and the second modulator. The instructions, when executed by at least one processor, individually and/or collectively, may cause the electronic device to: activate the first modulator and the second modulator, based on identifying a first event associated with satellite communication; and supply power of a first voltage or higher to the first PA, based on controlling at least one switch among a plurality of switches included in each of the activated first modulator and second modulator. The instructions, when executed by the first modulator or the second modulator, may cause the electronic device to monitor an input voltage to the first PA based on the power of the first voltage or higher being supplied; and activate a ground switch connected to a ground corresponding to the first modulator or the second modulator by changing an output signal from a ramping oscillator, based on a second period, based on a first signal associated with the satellite communication being input to the first PA supplied with the power.

According to an example embodiment, a non-transitory computer-readable storage medium may store at least one instruction, which, when executed by at least one processor of an electronic device, individually and/or collectively, may cause the electronic device to perform at least one operation comprising: activating a first modulator of the electronic device and a second modulator of the electronic device, based on identifying a first event associated with satellite communication; supplying power of a first voltage or higher to a first PA of the electronic device electrically connected to the first modulator and the second modulator through a switch, based on controlling at least one switch among a plurality of switches included in each of the activated first modulator and second modulator; monitoring, by the first modulator or the second modulator, an input voltage to the first PA based on the power of the first voltage or higher being supplied; and activating, by the first modulator or the second modulator, a ground switch connected to a ground corresponding to the first modulator or the second modulator, based on a second period, based on a first signal associated with the satellite communication being input to the first PA supplied with the power.

According to an example embodiment, a method of operating an electronic device may include: activating a first modulator of the electronic device and a second modulator of the electronic device, based on identifying a first event associated with satellite communication; supplying power of a first voltage or higher to a first PA of the electronic device electrically connected to the first modulator and the second modulator through a switch, based on controlling at least one switch among a plurality of switches included in each of the activated first modulator and second modulator; monitoring, by the first modulator or the second modulator, an input voltage to the first PA based on the power of the first voltage or higher being supplied; and activating, by the first modulator or the second modulator, a ground switch connected to a ground corresponding to the first modulator or the second modulator, based on a second period, based on a first signal associated with the satellite communication being input to the first PA supplied with the power.

### BRIEF DESCRIPTION OF THE DRAWINGS

The above and other aspects, features and advantages of certain embodiments of the present disclosure will be more apparent from the following detailed description, taken in conjunction with the accompanying drawings, in which:

FIG. 1 is a block diagram illustrating an example electronic device in a network environment according to various embodiments;

FIG. 2A is a block diagram illustrating an example configuration of an electronic device for supporting communication via a legacy network and communication via a 5G network according to various embodiments;

FIG. 2B is a block diagram illustrating an example configuration of an electronic device for supporting communication via a legacy network and communication via a 5G network according to various embodiments;

FIG. 3 is a diagram illustrating example access of an electronic device according to various embodiments;

FIG. 4 is a block diagram including a circuit diagram illustrating an example configuration of an electronic device for supporting communication via a non-terrestrial network according to various embodiments;

FIG. 5 is a circuit diagram illustrating an example configuration of a modulator according to various embodiments;

FIG. 6A is a circuit diagram illustrating a step-down operation of a modulator according to various embodiments;

FIG. 6B is a graph illustrating a step-down operation of a modulator according to various embodiments;

FIG. 7A is a circuit diagram illustrating a step-up operation of a modulator according to various embodiments;

FIG. 7B is a graph illustrating a step-up operation of a modulator according to various embodiments;

FIG. 8 is a circuit diagram illustrating an example of supplying power to a power amplifier through a plurality of modulators according to various embodiments;

FIG. 9 is a circuit diagram illustrating an example circuit of a modulator according to various embodiments;

FIG. 10 is a flowchart illustrating an example method of operating an electronic device according to various embodiments;

FIG. 11 is a circuit diagram an example of controlling a modulator of an electronic device according to various embodiments;

FIG. 12A is a graph illustrating an example operation of an electronic device according to a comparative example for comparison with various embodiments;

FIG. 12B is a graph illustrating an example operation of an electronic device according to various embodiments;

FIG. 13 is a block diagram illustrating an example configuration of an electronic device according to various embodiments;

FIG. 14 is a flowchart illustrating an example method of operating an electronic device according to various embodiments;

FIG. 15 is a graph illustrating an example operation of an electronic device according to various embodiments; and

FIG. 16 is a flowchart illustrating an example method of operating an electronic device according to various embodiments.

### DETAILED DESCRIPTION

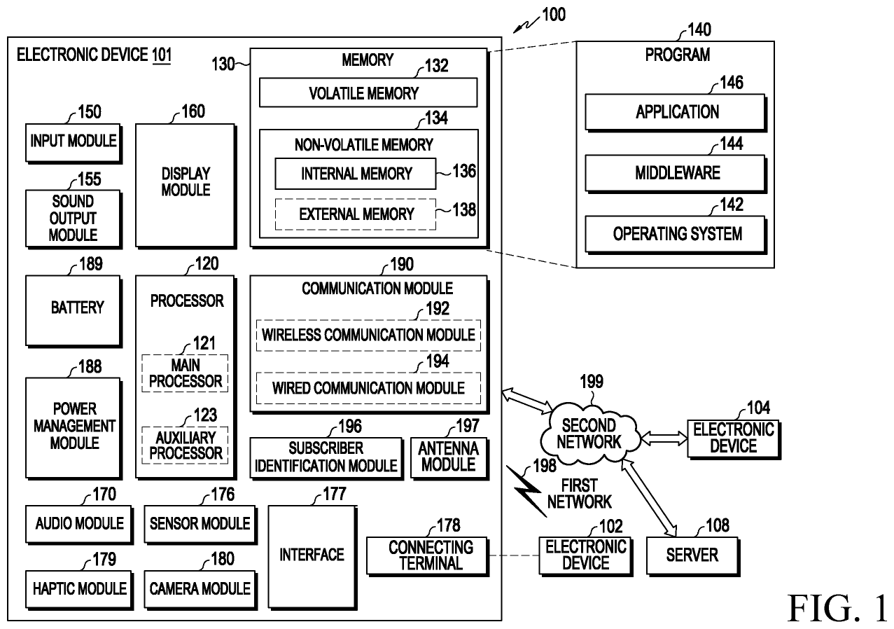

FIG. 1 is a block diagram illustrating an example electronic device 101 in a network environment 100 according to embodiments. Referring to FIG. 1, the electronic device 101 in the network environment 100 may communicate with an electronic device 102 via a first network 198 (e.g., a short-range wireless communication network), or at least one of an electronic device 104 or a server 108 via a second network 199 (e.g., a long-range wireless communication network). According to an embodiment, the electronic device 101 may communicate with the electronic device 104 via the server 108. According to an embodiment, the electronic device 101 may include a processor 120, memory 130, an input module 150, a sound output module 155, a display module 160, an audio module 170, a sensor module 176, an interface 177, a connecting terminal 178, a haptic module 179, a camera module 180, a power management module 188, a battery 189, a communication module 190, a subscriber identification module (SIM) 196, or an antenna module 197. In various embodiments, at least one of the components (e.g., the connecting terminal 178) may be omitted from the electronic device 101, or one or more other components may be added in the electronic device 101. In various embodiments, some of the components (e.g., the sensor module 176, the camera module 180, or the antenna module 197) may be implemented as a single component (e.g., the display module 160).

The processor 120 may include various processing circuitry and/or multiple processors. For example, as used herein, including the claims, the term “processor” may include various processing circuitry, including at least one processor, wherein one or more of at least one processor, individually and/or collectively in a distributed manner, may be configured to perform various functions described herein. As used herein, when “a processor”, “at least one processor”, and “one or more processors” are described as being configured to perform numerous functions, these terms cover situations, for example and without limitation, in which one processor performs some of recited functions and another processor(s) performs other of recited functions, and also situations in which a single processor may perform all recited functions. Additionally, the at least one processor may include a combination of processors performing various of the recited/disclosed functions, e.g., in a distributed manner. At least one processor may execute program instructions to achieve or perform various functions. The processor 120 may execute, for example, software (e.g., a program 140) to control at least one other component (e.g., a hardware or software component) of the electronic device 101 coupled with the processor 120, and may perform various data processing or computation. According to an embodiment, as at least part of the data processing or computation, the processor 120 may store a command or data received from another component (e.g., the sensor module 176 or the communication module 190) in volatile memory 132, process the command or the data stored in the volatile memory 132, and store resulting data in non-volatile memory 134. According to an embodiment, the processor 120 may include a main processor 121 (e.g., a central processing unit (CPU) or an application processor (AP)), or an auxiliary processor 123 (e.g., a graphics processing unit (GPU), a neural processing unit (NPU), an image signal processor (ISP), a sensor hub processor, or a communication processor (CP)) that is operable independently from, or in conjunction with, the main processor 121. For example, when the electronic device 101 includes the main processor 121 and the auxiliary processor 123, the auxiliary processor 123 may be adapted to consume less power than the main processor 121, or to be specific to a specified function. The auxiliary processor 123 may be implemented as separate from, or as part of the main processor 121.

The auxiliary processor 123 may control at least some of functions or states related to at least one component (e.g., the display module 160, the sensor module 176, or the communication module 190) among the components of the electronic device 101, instead of the main processor 121 while the main processor 121 is in an inactive (e.g., sleep) state, or together with the main processor 121 while the main processor 121 is in an active state (e.g., executing an application). According to an embodiment, the auxiliary processor 123 (e.g., an image signal processor or a communication processor) may be implemented as part of another component (e.g., the camera module 180 or the communication module 190) functionally related to the auxiliary processor 123. According to an embodiment, the auxiliary processor 123 (e.g., the neural processing unit) may include a hardware structure specified for artificial intelligence model processing. An artificial intelligence model may be generated by machine learning. Such learning may be performed, e.g., by the electronic device 101 where the artificial intelligence is performed or via a separate server (e.g., the server 108). Learning algorithms may include, but are not limited to, e.g., supervised learning, unsupervised learning, semi-supervised learning, or reinforcement learning. The artificial intelligence model may include a plurality of artificial neural network layers. The artificial neural network may be a deep neural network (DNN), a convolutional neural network (CNN), a recurrent neural network (RNN), a restricted Boltzmann machine (RBM), a deep belief network (DBN), a bidirectional recurrent deep neural network (BRDNN), deep Q-network or a combination of two or more thereof but is not limited thereto. The artificial intelligence model may, additionally or alternatively, include a software structure other than the hardware structure.

The memory 130 may store various data used by at least one component (e.g., the processor 120 or the sensor module 176) of the electronic device 101. The various data may include, for example, software (e.g., the program 140) and input data or output data for a command related thereto. The memory 130 may include the volatile memory 132 or the non-volatile memory 134.

The program 140 may be stored in the memory 130 as software, and may include, for example, an operating system (OS) 142, middleware 144, or an application 146.

The input module 150 may receive a command or data to be used by another component (e.g., the processor 120) of the electronic device 101, from the outside (e.g., a user) of the electronic device 101. The input module 150 may include, for example, a microphone, a mouse, a keyboard, a key (e.g., a button), or a digital pen (e.g., a stylus pen).

The sound output module 155 may output sound signals to the outside of the electronic device 101. The sound output module 155 may include, for example, a speaker or a receiver. The speaker may be used for general purposes, such as playing multimedia or playing record. The receiver may be used for receiving incoming calls. According to an embodiment, the receiver may be implemented as separate from, or as part of the speaker.

The display module 160 may visually provide information to the outside (e.g., a user) of the electronic device 101. The display module 160 may include, for example, a display, a hologram device, or a projector and control circuitry to control a corresponding one of the display, hologram device, and projector. According to an embodiment, the display module 160 may include a touch sensor adapted to detect a touch, or a pressure sensor adapted to measure the intensity of force incurred by the touch.

The audio module 170 may convert a sound into an electrical signal and vice versa. According to an embodiment, the audio module 170 may obtain the sound via the input module 150, or output the sound via the sound output module 155 or a headphone of an external electronic device (e.g., an electronic device 102) directly (e.g., wiredly) or wirelessly coupled with the electronic device 101.

The sensor module 176 may detect an operational state (e.g., power or temperature) of the electronic device 101 or an environmental state (e.g., a state of a user) external to the electronic device 101, and then generate an electrical signal or data value corresponding to the detected state. According to an embodiment, the sensor module 176 may include, for example, a gesture sensor, a gyro sensor, an atmospheric pressure sensor, a magnetic sensor, an acceleration sensor, a grip sensor, a proximity sensor, a color sensor, an infrared (IR) sensor, a biometric sensor, a temperature sensor, a humidity sensor, or an illuminance sensor.

The interface 177 may support one or more specified protocols to be used for the electronic device 101 to be coupled with the external electronic device (e.g., the electronic device 102) directly (e.g., wiredly) or wirelessly. According to an embodiment, the interface 177 may include, for example, a high definition multimedia interface (HDMI), a universal serial bus (USB) interface, a secure digital (SD) card interface, or an audio interface.

A connecting terminal 178 may include a connector via which the electronic device 101 may be physically connected with the external electronic device (e.g., the electronic device 102). According to an embodiment, the connecting terminal 178 may include, for example, a HDMI connector, a USB connector, a SD card connector, or an audio connector (e.g., a headphone connector).

The haptic module 179 may convert an electrical signal into a mechanical stimulus (e.g., a vibration or a movement) or electrical stimulus which may be recognized by a user via his tactile sensation or kinesthetic sensation. According to an embodiment, the haptic module 179 may include, for example, a motor, a piezoelectric element, or an electric stimulator.

The camera module 180 may capture a still image or moving images. According to an embodiment, the camera module 180 may include one or more lenses, image sensors, image signal processors, or flashes.

The power management module 188 may manage power supplied to the electronic device 101. According to an embodiment, the power management module 188 may be implemented as at least part of, for example, a power management integrated circuit (PMIC).

The battery 189 may supply power to at least one component of the electronic device 101. According to an embodiment, the battery 189 may include, for example, a primary cell which is not rechargeable, a secondary cell which is rechargeable, or a fuel cell.

The communication module 190 may support establishing a direct (e.g., wired) communication channel or a wireless communication channel between the electronic device 101 and the external electronic device (e.g., the electronic device 102, the electronic device 104, or the server 108) and performing communication via the established communication channel. The communication module 190 may include one or more communication processors that are operable independently from the processor 120 (e.g., the application processor (AP)) and supports a direct (e.g., wired) communication or a wireless communication. According to an embodiment, the communication module 190 may include a wireless communication module 192 (e.g., a cellular communication module, a short-range wireless communication module, or a global navigation satellite system (GNSS) communication module) or a wired communication module 194 (e.g., a local area network (LAN) communication module or a power line communication (PLC) module). A corresponding one of these communication modules may communicate with the external electronic device 104 via the first network 198 (e.g., a short-range communication network, such as Bluetooth™, wireless-fidelity (Wi-Fi) direct, or infrared data association (IrDA)) or the second network 199 (e.g., a long-range communication network, such as a legacy cellular network, a 5G network, a next-generation communication network, the Internet, or a computer network (e.g., LAN or wide area network (WAN)). These various types of communication modules may be implemented as a single component (e.g., a single chip), or may be implemented as multi components (e.g., multi chips) separate from each other. The wireless communication module 192 may identify and authenticate the electronic device 101 in a communication network, such as the first network 198 or the second network 199, using subscriber information (e.g., international mobile subscriber identity (IMSI)) stored in the subscriber identification module 196.

The wireless communication module 192 may support a 5G network, after a 4G network, and next-generation communication technology, e.g., new radio (NR) access technology. The NR access technology may support enhanced mobile broadband (eMBB), massive machine type communications (mMTC), or ultra-reliable and low-latency communications (URLLC). The wireless communication module 192 may support a high-frequency band (e.g., the mmWave band) to achieve, e.g., a high data transmission rate. The wireless communication module 192 may support various technologies for securing performance on a high-frequency band, such as, e.g., beamforming, massive multiple-input and multiple-output (massive MIMO), full dimensional MIMO (FD-MIMO), array antenna, analog beam-forming, or large scale antenna. The wireless communication module 192 may support various requirements specified in the electronic device 101, an external electronic device (e.g., the electronic device 104), or a network system (e.g., the second network 199). According to an embodiment, the wireless communication module 192 may support a peak data rate (e.g., 20 Gbps or more) for implementing eMBB, loss coverage (e.g., 164 dB or less) for implementing mMTC, or U-plane latency (e.g., 0.5 ms or less for each of downlink (DL) and uplink (UL), or a round trip of 1 ms or less) for implementing URLLC.

The antenna module 197 may transmit or receive a signal or power to or from the outside (e.g., the external electronic device) of the electronic device 101. According to an embodiment, the antenna module 197 may include an antenna including a radiating element including a conductive material or a conductive pattern formed in or on a substrate (e.g., a printed circuit board (PCB)). According to an embodiment, the antenna module 197 may include a plurality of antennas (e.g., array antennas). In such a case, at least one antenna appropriate for a communication scheme used in the communication network, such as the first network 198 or the second network 199, may be selected, for example, by the communication module 190 (e.g., the wireless communication module 192) from the plurality of antennas. The signal or the power may then be transmitted or received between the communication module 190 and the external electronic device via the selected at least one antenna. According to an embodiment, another component (e.g., a radio frequency integrated circuit (RFIC)) other than the radiating element may be additionally formed as part of the antenna module 197.

According to an embodiment, the antenna module 197 may form a mmWave antenna module. According to an embodiment, the mmWave antenna module may include a printed circuit board, a RFIC disposed on a first surface (e.g., the bottom surface) of the printed circuit board, or adjacent to the first surface and capable of supporting a designated high-frequency band (e.g., the mmWave band), and a plurality of antennas (e.g., array antennas) disposed on a second surface (e.g., the top or a side surface) of the printed circuit board, or adjacent to the second surface and capable of transmitting or receiving signals of the designated high-frequency band.

At least some of the above-described components may be coupled mutually and communicate signals (e.g., commands or data) therebetween via an inter-peripheral communication scheme (e.g., a bus, general purpose input and output (GPIO), serial peripheral interface (SPI), or mobile industry processor interface (MIPI)).

According to an embodiment, commands or data may be transmitted or received between the electronic device 101 and the external electronic device 104 via the server 108 coupled with the second network 199. Each of the electronic devices 102 or 104 may be a device of a same type as, or a different type, from the electronic device 101. According to an embodiment, all or some of operations to be executed at the electronic device 101 may be executed at one or more of the external electronic devices 102, 104, or 108. For example, if the electronic device 101 should perform a function or a service automatically, or in response to a request from a user or another device, the electronic device 101, instead of, or in addition to, executing the function or the service, may request the one or more external electronic devices to perform at least part of the function or the service. The one or more external electronic devices receiving the request may perform the at least part of the function or the service requested, or an additional function or an additional service related to the request, and transfer an outcome of the performing to the electronic device 101. The electronic device 101 may provide the outcome, with or without further processing of the outcome, as at least part of a reply to the request. To that end, a cloud computing, distributed computing, mobile edge computing (MEC), or client-server computing technology may be used, for example. The electronic device 101 may provide ultra low-latency services using, e.g., distributed computing or mobile edge computing. In an embodiment, the external electronic device 104 may include an internet-of-things (IoT) device. The server 108 may be an intelligent server using machine learning and/or a neural network. According to an embodiment, the external electronic device 104 or the server 108 may be included in the second network 199. The electronic device 101 may be applied to intelligent services (e.g., smart home, smart city, smart car, or healthcare) based on 5G communication technology or IoT-related technology.

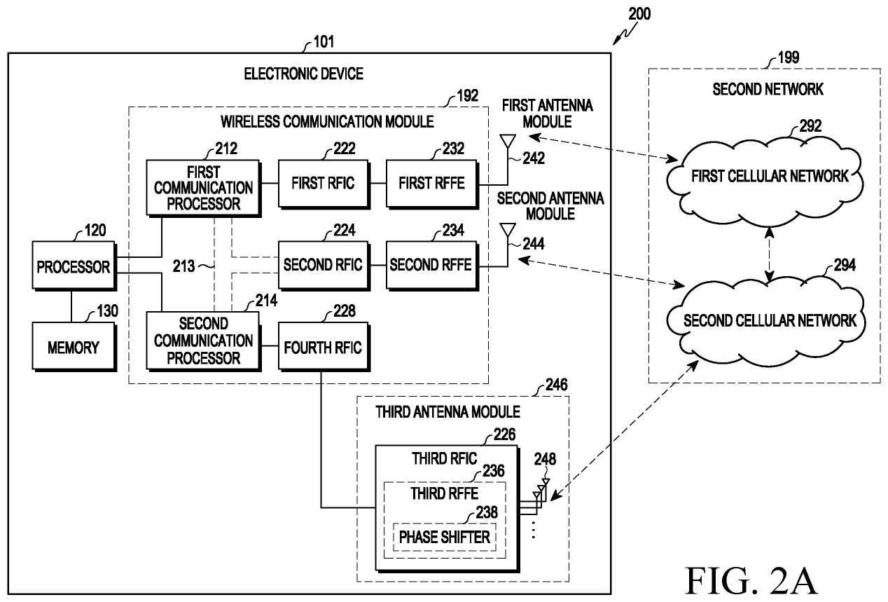

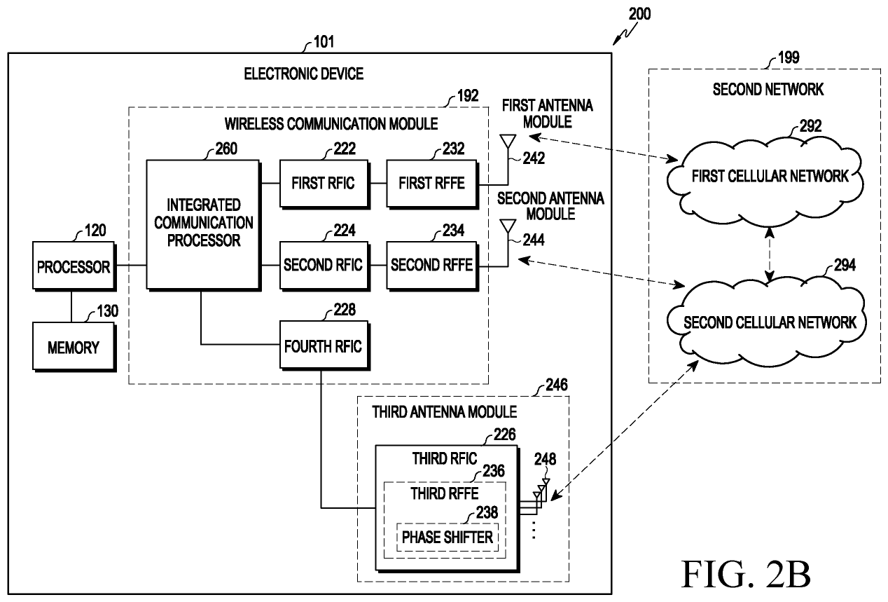

FIG. 2A is a block diagram 200 illustrating an example configuration of an electronic device 101 for supporting communication via a legacy network and communication via a 5G network according to various embodiments. Referring to FIG. 2A, the electronic device 101 may include a first communication processor (e.g., including processing circuitry) 212, a second communication processor (e.g., including processing circuitry) 214, a first radio-frequency integrated circuit (RFIC) 222, a second RFIC 224, a third RFIC 226, a fourth RFIC 228, a first radio-frequency front end (RFFE) 232, a second RFFE 234, a first antenna module (e.g., including at least one antenna) 242, a second antenna module (e.g., including at least one antenna) 244, a third antenna module (e.g., including at least one antenna) 246, and antennas 248. The electronic device 101 may further include a processor (e.g., including processing circuitry) 120 and memory 130. A second network 199 may include a first cellular network 292 and a second cellular network 294. According to an embodiment, the electronic device 101 may further include at least one of the components illustrated in FIG. 1, and the second network 199 may further include at least one different network. According to an embodiment, the first communication processor 212, the second communication processor 214, the first RFIC 222, the second RFIC 224, the fourth RFIC 228, the first RFFE 232, and the second RFFE 234 may form at least part of a wireless communication module 192. According to an embodiment, the fourth RFIC 228 may be omitted or may be included as part of the third RFIC 226.

The first communication processor 212 may include various processing circuitry and/or multiple processors. For example, as used herein, including the claims, the term “processor” may include various processing circuitry, including at least one processor, wherein one or more of at least one processor, individually and/or collectively in a distributed manner, may be configured to perform various functions described herein. As used herein, when “a processor”, “at least one processor”, and “one or more processors” are described as being configured to perform numerous functions, these terms cover situations, for example and without limitation, in which one processor performs some of recited functions and another processor(s) performs other of recited functions, and also situations in which a single processor may perform all recited functions. Additionally, the at least one processor may include a combination of processors performing various of the recited/disclosed functions, e.g., in a distributed manner. At least one processor may execute program instructions to achieve or perform various functions. The first communication processor 212 may, for example, establish a communication channel in a band to be used for wireless communication with the first cellular network 292 and may support communication via a legacy network through the established communication channel. According to embodiments, the first cellular network may be a legacy network including a second-generation (2G), 3G, 4G, or long-term evolution (LTE) network. The second communication processor 214 may include various processing circuitry and/or multiple processors. For example, as used herein, including the claims, the term “processor” may include various processing circuitry, including at least one processor, wherein one or more of at least one processor, individually and/or collectively in a distributed manner, may be configured to perform various functions described herein. As used herein, when “a processor”, “at least one processor”, and “one or more processors” are described as being configured to perform numerous functions, these terms cover situations, for example and without limitation, in which one processor performs some of recited functions and another processor(s) performs other of recited functions, and also situations in which a single processor may perform all recited functions. Additionally, the at least one processor may include a combination of processors performing various of the recited/disclosed functions, e.g., in a distributed manner. At least one processor may execute program instructions to achieve or perform various functions. The second communication processor 214 may, for example, establish a communication channel corresponding to a specified band (e.g., about 6 GHz to about 60 GHZ) in a band to be used for wireless communication with the second cellular network 294 and may support communication via a 5G network through the established communication channel. According to embodiments, the second cellular network 294 may be a 5G network defined by the 3GPP. In addition, according to an embodiment, the first communication processor 212 or the second communication processor 214 may establish a communication channel corresponding to a different specified band (e.g., about 6 GHz or lower) in the band to be used for wireless communication with the second cellular network 294 and may support communication via a 5G network through the established communication channel.

The first communication processor 212 may transmit and receive data to and from the second communication processor 214. For example, data classified to be transmitted through the second cellular network 294 may be changed to be transmitted through the first cellular network 292. In this case, the first communication processor 212 may receive the data to be transmitted from the second communication processor 214. For example, the first communication processor 212 may transmit and receive data to and from the second communication processor 214 through an inter-processor interface 213. The inter-processor interface 213 may be configured, for example, as a universal asynchronous receiver/transmitter (UART, e.g., high-speed UART (HS-UART)) or peripheral component interconnect express (PCIe) bus interface but is not limited in type. Alternatively, the first communication processor 212 and the second communication processor 214 may exchange control information and packet data information, for example, using shared memory. The first communication processor 212 may transmit and receive various types of information, such as sensing information, output strength information, and resource block (RB) allocation information, to and from the second communication processor 214.

The first communication processor 212 may not be directly connected to the second communication processor 214 depending on a configuration. In this case, the first communication processor 212 may transmit and receive data to and from the second communication processor 214 via a processor 120 (e.g., an application processor). For example, the first communication processor 212 and the second communication processor 214 may transmit and receive data to and from each other through the processor 120 (e.g., the application processor) and an HS-UART interface or a PCle interface, but the type of an interface is not limited. Alternatively, the first communication processor 212 and the second communication processor 214 may exchange control information and packet data information using the processor 120 (e.g., the application processor) and shared memory.

According to an embodiment, the first communication processor 212 and the second communication processor 214 may be configured in a single chip or a single package. According to embodiments, the first communication processor 212 or the second communication processor 214 may be configured along with the processor 120, a coprocessor 123, or a communication module 190 in a single chip or a single package. For example, as illustrated in FIG. 2B, an integrated communication processor 260 may support functions for communication with both the first cellular network 292 and the second cellular network 294.

As described above, at least one of the processor 120, the first communication processor 212, the second communication processor 214, or the integrated communication processor 260 may be configured as a single chip or a single package. In this case, the single chip or the single package may include memory (or storage device) configured to store an instruction to cause at least some of operations performed according to embodiments to be performed and a processing circuit (or operational circuit, not limited in term) configured to execute the instruction.

In transmission, the first RFIC 222 may convert a baseband signal generated by the first communication processor 212 into a radio-frequency (RF) signal of about 700 MHz to about 3 GHz used for the first cellular network 292 (e.g., a legacy network). In reception, an RF signal may be obtained from the first network 292 (e.g., the legacy network) through an antenna (e.g., the first antenna module 242) and may be preprocessed by an RFFE (e.g., the first RFFE 232). The first RFIC 222 may convert the preprocessed RF signal into a baseband signal to be processed by the first communication processor 212.

In transmission, the second RFIC 224 may convert a baseband signal generated by the first communication processor 212 or the second communication processor 214 into an RF signal (hereinafter, “5G sub-6 RF signal”) in a sub-6 band (e.g., about 6 GHz or lower) used for the second cellular network 294 (e.g., a 5G network). In reception, a 5G sub-6 RF signal may be obtained from the second cellular network 294 (e.g., the 5G network) through an antenna (e.g., the second antenna module 244) and may be preprocessed by an RFFE (e.g., the second RFFE 234). The second RFIC 224 may convert the preprocessed 5G sub-6 RF signal into a baseband signal to be processed by a corresponding communication processor of the first communication processor 212 or the second communication processor 214.

The third RFIC 226 may convert a baseband signal generated by the second communication processor 214 into an RF signal (hereinafter, “5G above-6 RF signal”) in a 5G above-6 band (e.g., about 6 GHz to about 60 GHZ) used for the second cellular network 294 (e.g., the 5G network). In reception, a 5G above-6 RF signal may be obtained from the second cellular network 294 (e.g., the 5G network) through an antenna (e.g., an antenna 248) and may be preprocessed by the third RFFE 236. The third RFIC 226 may convert the preprocessed 5G above-6 RF signal into a baseband signal to be processed by the second communication processor 214. According to an embodiment, the third RFFE 236 may be configured as part of the third RFIC 226.

According to an embodiment, the electronic device 101 may include a fourth RFIC 228 separately from the third RFIC 226 or as at least part of the third RFIC 226. In this case, the fourth RFIC 228 may convert a baseband signal generated by the second communication processor 214 into an RF signal (hereinafter, “IF signal”) in an intermediate frequency band (e.g., about 9 GHz to about 11 GHZ) and may transmit the IF signal to the third RFIC 226. The third RFIC 226 may convert the IF signal into a 5G above-6 RF signal. In reception, a 5G above-6 RF signal may be received from the second cellular network 294 (e.g., the 5G network) through an antenna (e.g., the antenna 248) and may be converted into an IF signal by the third RFIC 226. The fourth RFIC 228 may convert the IF signal into a baseband signal to be processed by the second communication processor 214.

According to an embodiment, the first RFIC 222 and the second RFIC 224 may be configured as at least part of a single chip or a single package. According to embodiments, in FIG. 2A or FIG. 2B, when the first RFIC 222 and the second RFIC 224 are configured as a single chip or a single package, the first RFIC 222 and the second RFIC 224 may be configured as an integrated RFIC. In this case, the integrated RFIC may be connected to the first RFFE 232 and the second RFFE 234, thus converting a baseband signal into a signal in a band supported by the first RFFE 232 and/or the second RFFE 234, and transmitting the converted signal to one of the first RFFE 232 and the second RFFE 234. According to an embodiment, the first RFFE 232 and the second RFFE 234 may be configured as at least part of a single chip or a single package. According to an embodiment, at least one of the first antenna module 242 or the second antenna module 244 may be omitted or may be combined with a different antenna module to process corresponding RF signals in a plurality of bands.

According to an embodiment, the third RFIC 226 and the antenna 248 may be disposed on the same substrate to form a third antenna module 246. For example, the communication module 192 or the processor 120 may be disposed on a first substrate (e.g., a main PCB). In this case, the third RFIC 226 may be disposed in a portion (e.g., a lower surface) of a second substrate (e.g., a sub-PCB) separate from the first substrate, and the antenna 248 may be disposed in another portion (e.g., an upper surface), thereby forming the third antenna module 246. The third RFIC 226 and the antenna 248 may be disposed on the same substrate, thereby reducing the length of a transmission line therebetween, which may reduce loss (e.g., attenuation) of, for example, a signal in a high-frequency band (e.g., about 6 GHz to about 60 GHZ) used for communication via a 5G network due to the transmission line. Accordingly, the electronic device 101 may improve the quality or speed of communication with the second network 294 (e.g., the 5G network).

According to an embodiment, the antenna 248 may be configured as an antenna array including a plurality of antenna elements which may be used for beamforming. In this case, the third RFIC 226 may include, for example, a plurality of phase shifters 238 corresponding to the plurality of antenna elements as part of the third RFFE 236. In transmission, each of the plurality of phase shifters 238 may convert the phase of a 5G above-6 RF signal to be transmitted to an external device (e.g., a base station of the 5G network) of the electronic device 101 through a corresponding antenna element. In reception, each of the plurality of phase shifters 238 may convert the phase of a 5G above-6 RF signal received from the outside through a corresponding antenna element into the same phase or substantially the same phase. This enables transmission or reception through beamforming between the electronic device 101 and the outside.

The second cellular network 294 (e.g., the 5G network) may operate independently of the first cellular network 292 (e.g., the legacy network) (e.g., stand-alone (SA) mode) or may be connected to operate (e.g., non-stand-alone (NSA) mode). For example, the 5G network may have only an access network (e.g., a 5G radio access network (RAN) or a next-generation RAN (NG RAN)) and may not have a core network (e.g., a next-generation core (NGC)). In this case, after accessing the access network of the 5G network, the electronic device 101 may access an external network (e.g., the Internet) under control of a core network (e.g., an evolved packet core (EPC)) of the legacy network. Protocol information (e.g., LTE protocol information) for communication with the legacy network or protocol information (e.g., new radio (NR) protocol information) for communication with the 5G network may be stored in memory 230, and may be accessed by a different component (e.g., the processor 120, the first communication processor 212, or the second communication processor 214).

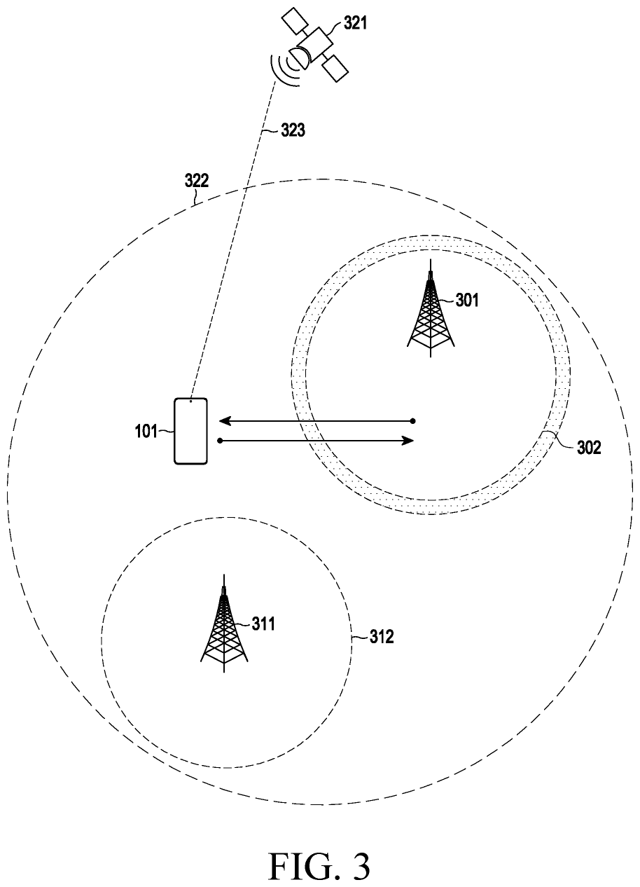

FIG. 3 is a diagram illustrating example access of an electronic device according to various embodiments.

According to an embodiment, the electronic device 101 may be located within coverage 322 of a satellite 321. Those skilled in the art will understand that the satellite 321 may be replaced with another type of electronic device that supports non-terrestrial communication in the disclosure. The electronic device 101 may access (323) to the satellite 321 within the coverage 322 of the satellite 321. For example, the electronic device 101 may perform a cell scan within the coverage 322 of the satellite 321. As a result of performing the cell scan, the electronic device 101 may identify the satellite 321 (that may be referred to as a cell corresponding to the satellite 321). When the satellite 321 satisfies a cell selection condition, the electronic device 101 may camp on the satellite 321. The electronic device 101 may camp on the satellite 321, and may perform at least one operation to establish connection (e.g., radio resource control (RRC) connection) with the satellite 321. The electronic device 101 may perform at least one operation for attachment to (or registration with) a core network (e.g., an MME or an AMF) corresponding to the satellite 321, based on the established connection. The access 323 to the satellite 321 may include, for example, camp-on, connection establishment, and/or attachment, but is not limited thereto. The coverage 322 of satellite communication may be relatively large (e.g., 50 times or more) compared to coverages 302 and 312 of terrestrial base stations 301 and 311. For example, the coverage 322 based on the satellite communication may cover an area that the coverages 302 and 312 based on terrestrial communication do not cover, thus enabling a user to perform communication using the electronic device 101 even in an area where terrestrial communication is not supported.

For example, the satellite communication based on the satellite 321 is likely to support a limited frequency resource and/or a limited service. The satellite communication may provide a limited service, for example, an emergency service (e.g. an emergency call) and/or a short message service (SMS), but may not provide other general data transmission and reception services (e.g., video streaming but not limited thereto). In an embodiment, the satellite communication is likely to support a limited bandwidth (e.g., 1.4 MHZ) compared to the terrestrial communication. For example, the satellite communication may have a relatively low total cell capacity of 2 to 4 Mbps even when supporting a voice call and/or a data services. However, the terrestrial communication may support a bandwidth of up to 100 MHz, for example, when carrier aggregation (CA) is activated, and may have a cell capacity exceeding 1 Gbps.

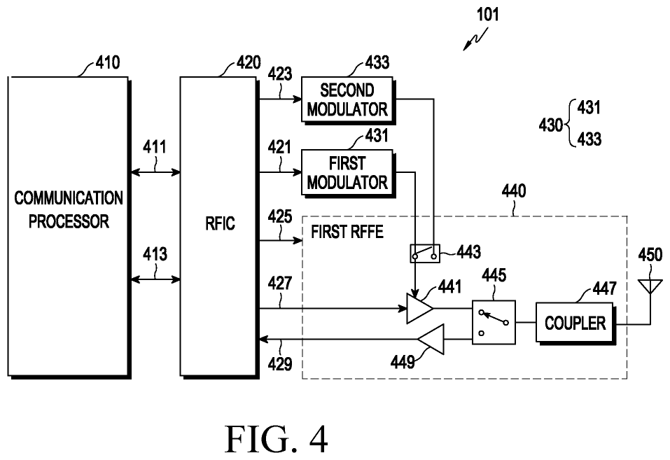

FIG. 4 is a block diagram illustrating an example configuration of an electronic device for supporting communication via a non-terrestrial network according to various embodiments.

Referring to FIG. 4, the electronic device 101 may include at least one communication processor (e.g., including processing circuitry) 410, at least one RFIC 420, at least one modulator 430, a first RFFE 440, and/or an antenna module (e.g., including at least one antenna) 450.

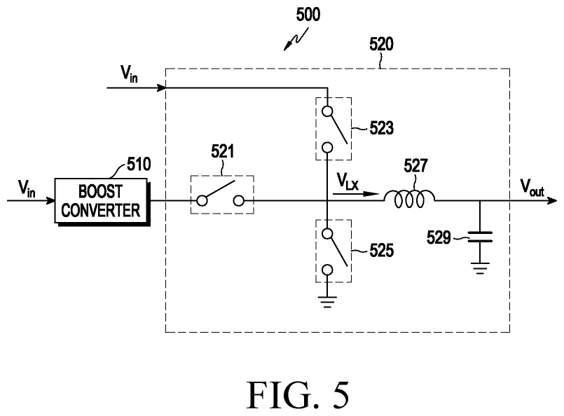

In an embodiment, the at least one communications processor 410 (e.g., the processor 120, the first communications processor 212, the second communications processor 214, and/or the integrated communications processor 260) may activate or deactivate at least one switch included in at least one modulator (e.g., the first modulator 431 or the second modulator 433). The communication processor 410 may activate or deactivate the at least one switch, based on transmitting a control signal to the at least one RFIC 420 through a control line 411. In an embodiment, the communication processor 410 may transmit a signal associated with transmission data to the RFIC 420 through at least one signal line 413. An operation of the communication processor 410 controlling the at least one RFIC 420 to reduce a risk of damage to a power amplifier (e.g., a first PA 441) included in at least one RFFE (e.g., the first RFFE 232, the second RFFE 234, the third RFFE 236, or the first RFFE 440) will be described in greater detail below with reference to FIG. 5 to FIG. 16.

In an embodiment, in transmission, the at least one RFIC 420 (e.g., the first RFIC 222, the second RFIC 224, the third RFIC 226, and/or the fourth RFIC 228) may output an RF signal in a frequency band corresponding to network communication through a transmission line 425. In reception, the at least one RFIC 420 may process an RF signal transmitted by the first RFFE 440 through a reception line 429. A signal converted into a baseband by the at least one RFIC 420 may be transmitted to the communication processor 410 through at least one signal line 413. In an embodiment, the at least one RFIC 420 may activate or deactivate the at least one switch included in the at least one modulator (e.g., the first modulator 431 or the second modulator 433), based on receiving a control signal from the communications processor 410 through a control line 411. For example, the at least one RFIC 420 may control the first modulator 431 to perform a switching operation through a control line 421, based on an MIPI. The at least one RFIC 420 may control the second modulator 433 to perform a switching operation through a control line 423, based on the MIPI. In an embodiment, the at least one RFIC 420 may control an operation of at least one switch (an SPST switch 443 or an SPDT switch 445) included in the first RFFE 440, based on transmitting a control signal to the first RFFE 440 through a control line 425.

In an embodiment, the at least one modulator 430 (e.g., the first modulator 431 or the second modulator 433) may be electrically connected to the at least one RFFE, and may supply power to the power amplifier (hereinafter, “PA”) included in the at least one RFFE. In an embodiment, the level of a voltage output by the at least one modulator 430 may change depending on the type of a communication network. In an embodiment, when transmitting and receiving a signal associated with a non-terrestrial communication network, the at least one modulator 430 may perform a step-up operation. When transmitting and receiving a signal associated with a communication network that requires relatively low transmission power, the at least one modulator 430 may perform a step-down operation. In an embodiment, the at least one modulator 430 may be electrically connected to a battery (e.g., the battery 189), and may perform a step-up or step-down operation, based on an output voltage V_{bat} of the battery. The at least one modulator 430 may turn on the PA, based on a step-up or step-down operation. In an embodiment, one modulator 431 or 433 may be connected to one or more PAs. In an embodiment, the at least one modulator 430 may be configured as an envelope tracking (ET) modulator that supports an ET mode or an average power tracking (APT) mode. Although not shown in FIG. 4, those skilled in the art will understand that the ET modulator may include a linear regulator to amplify an envelope of a signal and a switching converter. The ET modulator may include one or more charging and/or discharging capacitors to maintain an output voltage. In an embodiment, the ET modulator may supply power to the PA, based on switching between the ET mode and the APT mode. In an embodiment, the ET mode may be a mode in which the at least one modulator 430 supplies power of a level corresponding to required transmission power to the PA, based on tracking an envelope of a transmission signal. An envelope of a signal output from the RFIC 420 may be amplified by the linear regulator in the ET mode. The switching converter may supply a main current to the PA, based on the envelope amplified by the linear regulator. The APT mode may be a mode of providing a DC voltage corresponding to power of a transmission signal to the PA, based on a buck converter, a boost converter, and/or a buck-boost converter. In the APT mode, the switching converter may supply a DC voltage corresponding to a required power level of a transmission signal to the PA. Those skilled in the art will understand that, in an embodiment, the at least one modulator 430 may also be configured as a modulator that supports only the APT mode, based on a DC-DC converter. In an embodiment, the modulator may be referred to as a “power amplifier power management (PAPM).”

In an embodiment, the first RFFE 440 may process the RF signal corresponding to the network communication. The first RFFE 440 may include the first PA 441, the single-pole single-throw (SPST) switch 443, the single-pole double-throw (SPDT) switch 445, a coupler 447, and/or a low-noise amplifier (LNA) 449. In an embodiment, the first PA 441 may be turned on by power supplied through the first modulator 431 and/or the second modulator 433. In an embodiment, the first modulator 431 and/or the second modulator 433 may be electrically connected to the first PA 441, based on an operation of the SPST switch 443. The power supplied through the first modulator 431 and/or the second modulator 433 may correspond to a voltage modulated based on the output voltage of the battery 189. In an embodiment, the RF signal output from the at least one RFIC 420 through, for example, transmission line 427, may be amplified by the first PA 441. In an embodiment, in transmission, the SPDT switch 445 may electrically connect the first PA 441 and the antenna module 450, based on a control signal of at least one RFIC 420. Although FIG. 4 shows an operation in transmission, the SPDT switch 445 may electrically connect the LNA 449 and the antenna module 450, based on a control signal of at least one RFIC 420, in reception. In an embodiment, in transmission, the signal amplified by the first PA 441 may pass through the SPDT switch 445 and the coupler 447 to be transmitted to the antenna module 450. The coupler 447 may measure RF power from an RF source to a load and power reflected from the load to the source. In reception, the LNA 449 may amplify a signal received by the antenna module 450. The signal amplified by the LNA 449 may be transmitted to the at least one RFIC 420 through the reception line 429.

In an embodiment, the antenna module (e.g., the antenna module 197, the first antenna module 242, the second antenna module 244, the third antenna module 246, and/or the antennas 248) may radiate an RF signal or receive a signal from the outside. The antenna module 450 may transmit and receive, for example, a signal corresponding to non-terrestrial network communication. Although FIG. 4 shows only one antenna module for convenience of explanation, those skilled in the art will understand that the electronic device 101 includes a plurality of antenna modules. In an embodiment, in transmission, the antenna module 450 may transmit a signal corresponding to network communication (e.g., non-terrestrial network communication), based on a signal amplified by the first PA 441. In reception, the antenna module 450 may receive a signal corresponding to non-terrestrial network communication. The signal received by the antenna module 450 may be transmitted to the LNA 449 through the SPDT switch 445. The signal amplified by the LNA 449 may be transmitted to the at least one RFIC 420. In an embodiment, the electronic device 101 may further include the components illustrated in FIG. 1, FIG. 2A, or FIG. 2B in addition to the components illustrated in FIG. 4.

FIG. 5 is a circuit diagram illustrating an example circuit of a modulator according to various embodiments.

In an embodiment, referring to FIG. 5, the modulator 500 (e.g., the first modulator 431 and/or the second modulator 433) may include a boost converter 510 and a buck converter 520. For example, the modulator 500 may include a switching converter without a linear regulator. In an embodiment, the modulator 500 may support only an APT mode, and those skilled in the art will understand that the modulator 500 may also be configured as an ET modulator, as described above in FIG. 4. In an embodiment, the modulator 500 may supply modulated power to a PA, based on an operation of the boost converter 510 and/or the buck converter 520. In an embodiment, the boost converter 510 may perform a step-up operation, based on an output voltage Vᵢₙ of a battery (e.g., the battery 189).

In an embodiment, the buck converter 520 may include a first switch 521, a second switch 523, a ground switch 525, an inductor 527, and/or a bypass capacitor 529. In an embodiment, an output voltage of the boost converter 510 may be input to the buck converter 520, based on an operation of the first switch 521. In an embodiment, the output voltage of the battery 189 may be input to the buck converter 520, based on an operation of the second switch 523. In an embodiment, charges of the inductor 527 may be transmitted to a ground, based on an operation of the ground switch 525. In an embodiment, a current supplied through the battery or the boost converter 510 may charge the inductor 527. The current charged in the inductor 527 may be supplied to at least one PA (e.g., the first PA 441). In an embodiment, an AC component output by the inductor 527 may be transmitted to the ground by the bypass capacitor 529.

In an embodiment, when transmission of a relatively high-power signal is required and/or when linearity of the at least one PA is required, the modulator 500 may output a high voltage of the output voltage of the battery or higher, based on controlling the first switch 521 and/or the second switch 523. In an embodiment, the first switch 521 and the second switch 523 may be selectively activated based on a duty cycle while the modulator 500 is activated. Those skilled in the art will understand that a duty ratio between the output voltage of the boost converter 510 based on the operation of the first switch 521 and the output voltage of the battery based on the operation of the second switch 523 may change according to an embodiment of the disclosure. The modulator 500 may change the level of an output voltage Vₒᵤₜ supplied to the at least one PA, based on changing the duty cycle.

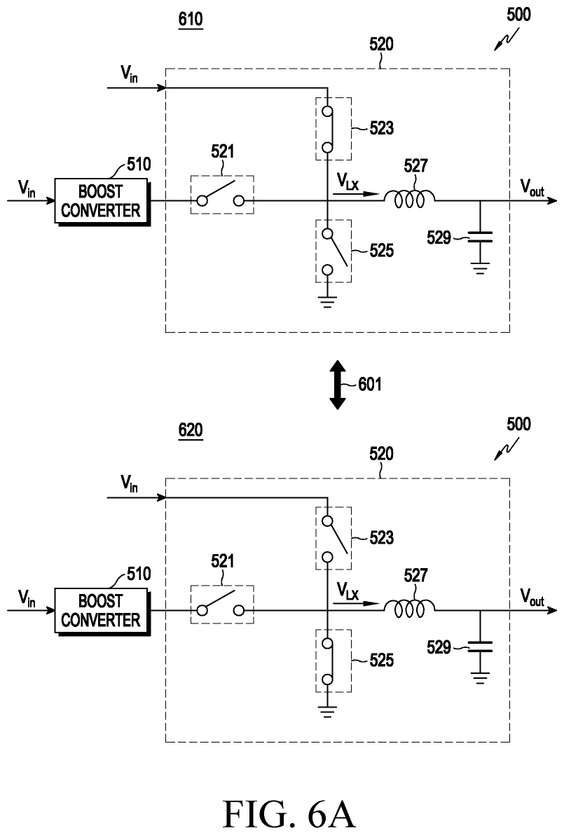

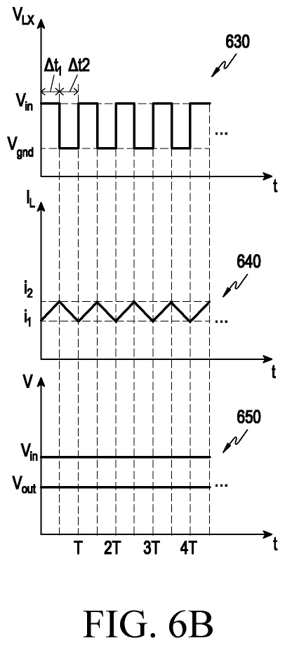

FIG. 6A is a circuit diagram illustrating a step-down operation of a modulator according to various embodiments.

In an embodiment, referring to FIG. 6A, the modulator 500 may perform a step-down operation, based on a switching operation 601 of a second switch 523 and/or a ground switch 525. A redundant description of a component performing the same operation as that of a component illustrated in FIG. 5 among components illustrated in FIG. 6A may not be repeated.

In an embodiment, referring to reference numeral 610, an output voltage Vᵢₙ of a battery may be input to an inductor 527, based on the second switch 523 being turned on. In an embodiment, the modulator 500 may perform the switching operation 601, based on a duty cycle. For example, the modulator 500 may turn off the second switch 523, and may turn on the ground switch 525. In an embodiment, referring to reference numeral 620, charges charged in the inductor 527 may be transmitted to a ground, based on the ground switch 525 being turned on. The modulator 500 may repeat the switching operation 601, based on the duty cycle. The level of a DC voltage Vₒᵤₜ output by the inductor 527 may be less than the level of the output voltage of the battery, based on the switching operation 601.

FIG. 6B is a graph illustrating a step-down operation of a modulator according to various embodiments.

In an embodiment, referring to a graph 630 showing the level of a voltage V_{LX} input to an inductor (e.g., the inductor 527) of the modulator (e.g., the modulator 500), an output voltage Vᵢₙ of a battery may be input to the inductor for Δt₁, based on a second switch (e.g., the second switch 523) being turned on. In an embodiment, a ground voltage V_{gnd} may be input to the inductor for Δt₂, based on a ground switch (e.g., the ground switch 525) being turned on. A switching operation of the modulator may be repeated, based on a period T.

In an embodiment, referring to a graph 640 showing the level of a current I_{L} charged in the inductor (e.g., the inductor 527) of the modulator (e.g., the modulator 500), the level of the current charged in the inductor may increase from i₁ to i₂ for Δt₁, based on the second switch (e.g., the second switch 523) being turned on. In an embodiment, the level of the current charged in the inductor may decrease from i₂ to i₁ for Δt₂, based on the ground switch (e.g., the ground switch 525) being turned on.

In an embodiment, referring to a graph 650 showing the level of an input and/or output voltage V of the modulator (e.g., the modulator 500), the level of the output voltage Vₒᵤₜ of the modulator may be less than the level of the input voltage Vᵢₙ of the modulator, based on a step-down operation of the modulator.

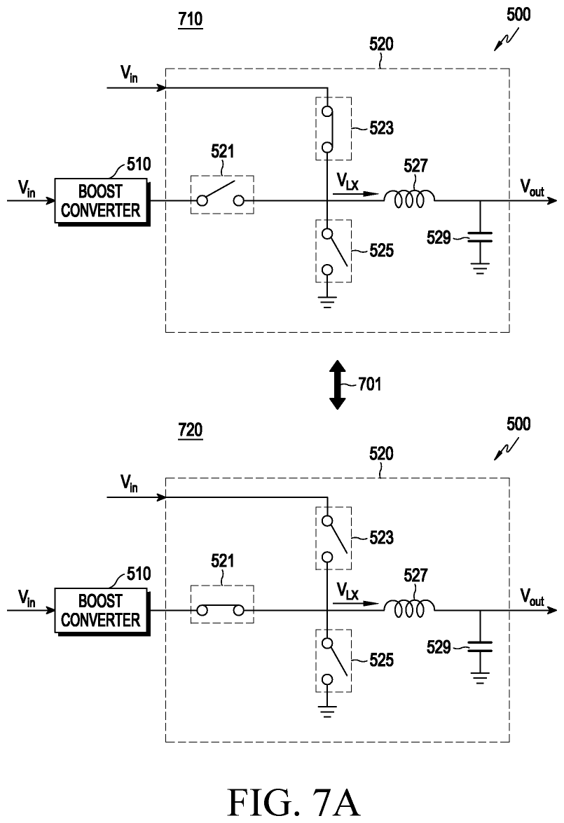

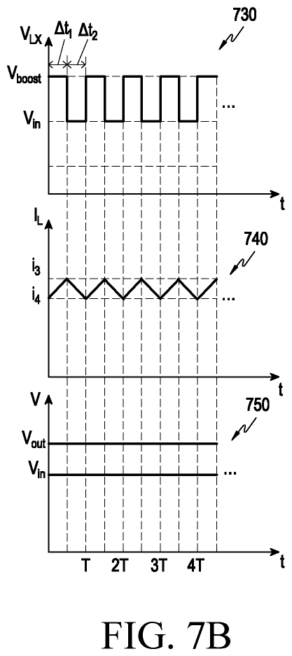

FIG. 7A is a circuit diagram illustrating a step-up operation of a modulator according to various embodiments.

In an embodiment, referring to FIG. 7A, the modulator 500 may perform a step-up operation, based on a switching operation 701 of a first switch 521 and/or a second switch 523. A redundant description of a component performing the same operation as that of a component illustrated in FIG. 5 among components illustrated in FIG. 7A may not be repeated.

In an embodiment, referring to reference numeral 710, an output voltage Vᵢₙ of a battery may be input to an inductor 527, based on the second switch 523 being turned on. In an embodiment, the modulator 500 may perform the switching operation 701, based on a duty cycle. For example, the modulator 500 may turn off the second switch 523, and may turn on the first switch 521. In an embodiment, referring to reference numeral 720, an output voltage of a boost converter 510 may be input to the inductor 527, based on the first switch 521 being turned on. The modulator 500 may repeat the switching operation 701, based on the duty cycle. The level of a DC voltage Vₒᵤₜ output by the inductor 527 may exceed the level of the output voltage of the battery, based on the switching operation 701.

FIG. 7B is a graph illustrating a step-up operation of a modulator according to various embodiments.

In an embodiment, referring to a graph 730 showing the level of a voltage V_{LX} input to an inductor (e.g., the inductor 527) of the modulator (e.g., the modulator 500), an output voltage of a boost converter (e.g., the boost converter 510) may be input to the inductor for Δt₁, based on a first switch (e.g., the first switch 521) being turned on. In an embodiment, an output voltage Vᵢₙ of a battery may be input to the inductor for Δt₂, based on a second switch (e.g., the second switch 523) being turned on. A switching operation of the modulator may be repeated, based on a period T.

In an embodiment, referring to a graph 740 showing the level of a current I_{L} charged in the inductor (e.g., the inductor 527) of the modulator (e.g., the modulator 500), the level of the current charged in the inductor may increase from i₃ to i₄ for Δt₁, based on the first switch (e.g., the first switch 521) being turned on. Although i₃ in FIG. 7B may be the same value as i₂ in FIG. 6B in an embodiment, those skilled in the art will understand that the specific value of i₃ is not necessarily limited thereto. In an embodiment, the level of the current charged in the inductor may decrease from i₄ to i₃ for Δt₂, based on the second switch (e.g., the second switch 523) being turned on.

In an embodiment, referring to a graph 750 showing the level of an input and/or output voltage V of the modulator (e.g., the modulator 500), the level of the output voltage Vₒᵤₜ of the modulator may be larger than the level of the input voltage Vᵢₙ of the modulator, based on a step-up operation of the modulator.

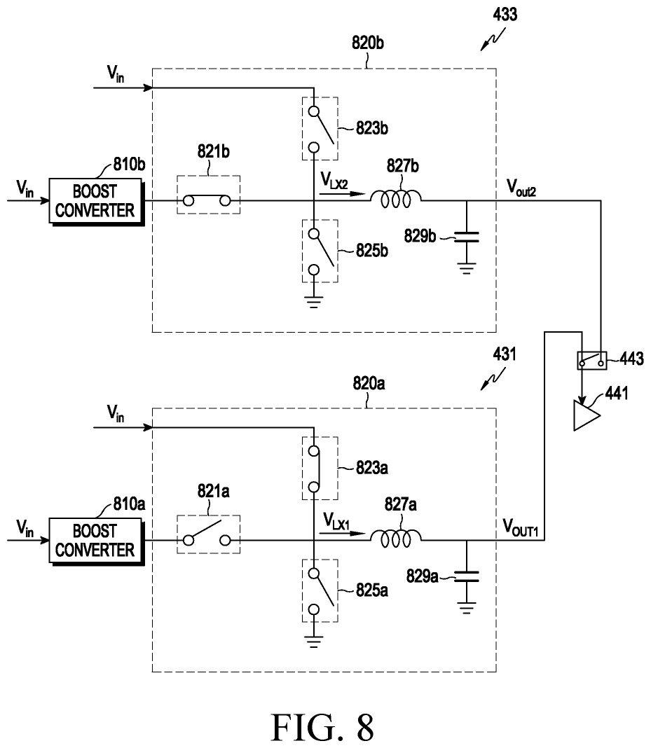

FIG. 8 is a circuit diagram illustrating an example of supplying power to a power amplifier through a plurality of modulators according to various embodiments.

In an embodiment, referring to FIG. 8, a first modulator 431 and/or a second modulator 433 may supply power to a first PA 441. In an embodiment, an SPST switch 443 may electrically connect the first modulator 431 and the second modulator 433 to the first PA 441. Those skilled in the art will understand that the first PA 441 and the SPST switch 443 are elements included in an RFFE (e.g., the first RFFE 440) as described above with reference to FIG. 4.

In an embodiment, a boost converter 810a of the first modulator and a boost converter 810b of the second modulator may perform substantially the same operation as that of the boost converter (e.g., the boost converter 510) of FIG. 5. In an embodiment, a buck converter 820a of the first modulator and a buck converter 820b of the second modulator may perform substantially the same operation as that of the buck converter (e.g., the buck converter 520) of FIG. 5. In an embodiment, a first switch 821a, a second switch 823a, a ground switch 825a, an inductor 827a, and a bypass capacitor 829a included in the buck converter 820a of the first modulator may function substantially the same as corresponding components included in the buck converter 520 of FIG. 5. In an embodiment, a first switch 821b, a second switch 823b, a ground switch 825b, an inductor 827b, and a bypass capacitor 829b included in the buck converter 820b of the second modulator may function substantially the same as the corresponding components included in the buck converter 520 of FIG. 5.

In an embodiment, when transmission of a relatively high-power signal is required as in non-terrestrial network communication, the first modulator 431 and the second modulator 433 may provide a boosted voltage to the first PA 441, based on controlling the first switches 821a and 821b and the second switches 823a and 823b. In an embodiment, the first modulator 431 and the second modulator 433 may relatively reduce a risk of damage to at least one modulator (e.g., the at least one modulator 430), based on outputting voltages of substantially the same potential. A level of an output voltage of the first modulator 431 may correspond to a level of an output voltage of the second modulator 433 while the power is supplied to the first PA 441. In an embodiment, when the first modulator 431 and the second modulator 433 each perform a step-up operation to output a target voltage, an overshoot of temporarily supplying a voltage higher than the target voltage to the first PA 441 may occur. In an embodiment, when an overshoot voltage exceeding an absolute maximum rating (AMR) of a PA is input, a risk of damage to the PA may relatively increase.

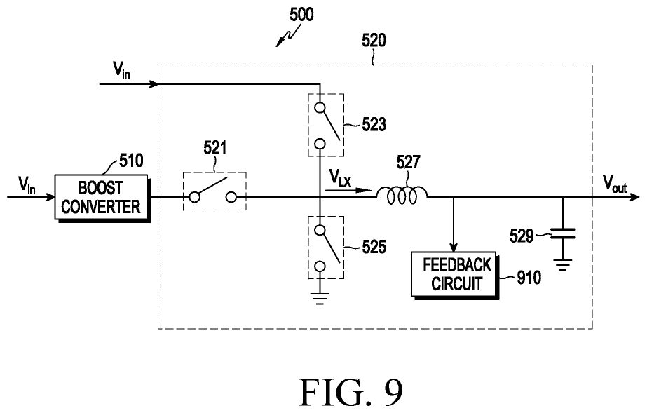

FIG. 9 is a circuit diagram illustrating an example circuit of a modulator according to an embodiment.

In an embodiment, referring to FIG. 9, the modulator (e.g., the modulator 500 of FIG. 5) may further include a feedback circuit 910. A redundant description of a component performing the same operation as that of a component illustrated in FIG. 5 among components illustrated in FIG. 9 may not be repeated. In an embodiment, the feedback circuit 910 may measure the level of a current input to at least one PA (e.g., the first PA 441). In an embodiment, the feedback circuit 910 may, for example, and without limitation, include a level shifter, a current sensor, and/or a control loop. In an embodiment, the level shifter may convert a signal input to the feedback circuit 910, based on a current charged in an inductor 527. The current sensor may identify the level of a current input to the PA 441, based on the signal converted by the level shifter. The control loop may control, based on the level of the current identified by the current sensor, the state of a ground switch 525 so that an output voltage of the modulator 500 is maintained below a threshold voltage. In an embodiment, a function and/or configuration of the feedback circuit 910 is not limited to the foregoing example. The modulator 500 may change the level of the output voltage of the modulator 500, based on the measured level of the current. For example, the modulator 500 may identify that a voltage input to the at least one PA is lower than a target voltage, based on the measured level of the current. The modulator 500 may increase the output voltage of the modulator 500, based on controlling at least one switch among a first switch 521, a second switch 523, or the ground switch 525. The modulator 500 may identify that the voltage input to the at least one PA is higher than the target voltage, based on the measured level of the current. The modulator 500 may reduce the output voltage of the modulator 500, based on controlling at least one switch among the first switch 521, the second switch 523, or the ground switch 525.

In an embodiment, in a transmission operation for accessing a non-terrestrial network, a plurality of modulators (e.g., the first modulator 431 and the second modulator 433 of FIG. 8) may be activated. In an embodiment, when the plurality of modulators supplies power to the at least one PA for transmission of a relatively high-power signal, about a double current may be input to the at least one PA, compared to when only one modulator supplies power to the at least one PA. In an embodiment, a voltage output by the inductor 527 may be reduced due to an IR drop due to wiring from Vₒᵤₜ to PA power. In an embodiment, when a relatively high-power RF signal is output, the feedback circuit 910 may detect a relatively large IR drop. The modulator 500 may temporarily supply a high current to the inductor 527, based on changing a duty cycle of the first switch 521 and the second switch 523, to restore the level of the output voltage reduced due to the IR drop. In an embodiment, a relatively high current charged in the inductor 527 may flow into the at least one PA even when the first switch 521 and the second switch 523 are turned off. In an embodiment, when a high current temporarily flows into the at least one PA, a risk of damage to the at least one PA may relatively be increased due to input of a voltage exceeding an AMR.

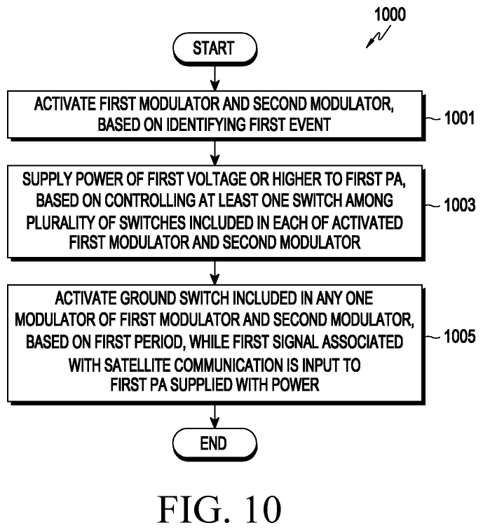

FIG. 10 is a flowchart 1000 illustrating an example method of operating an electronic device according to various embodiments.

According to an embodiment, in operation 1001, the electronic device 101 (e.g., the processor 120, the first communications processor 212, the second communications processor 214, the integrated communication processor 260, and/or the communications processor 410) may activate a first modulator (e.g., the first modulator 431) and a second modulator (e.g., the second modulator 433), based on identifying a first event. For example, the electronic device 101 may identify occurrence of the first event, based on identifying a user input to perform satellite communication. In an embodiment, the user input may be an event of touching at least a portion of a display module (e.g., the display module 160), but is not limited to the foregoing example.

In an embodiment, based on activating the first modulator and the second modulator, the electronic device 101 may supply power of a first voltage or higher to a first PA (e.g., the first PA 441), based on controlling at least one switch among a plurality of switches included in each of the activated first modulator and second modulator (e.g., the first switch 821a of the first modulator, the second switch 823a of the first modulator, the ground switch 825a of the first modulator, the first switch 821b of the second modulator, the second switch 823b of the second modulator, and the ground switch 825b of the second modulator) in operation 1003. In an embodiment, the first voltage may be a target voltage corresponding to the first PA required for non-terrestrial network communication. A redundant description of an operation of the plurality of modulators (e.g., the first modulator 431 and the second modulator 433) of FIG. 8 and operation 1003 may not be repeated.

In an embodiment, based on supplying the power of the first voltage or higher to the first PA, the electronic device 101 may activate a ground switch included in any one modulator of the first modulator and the second modulator, based on a first period, while inputting a first signal associated with satellite communication to the first PA supplied with the power in operation 1005. In an embodiment, the electronic device 101 may control at least one RFIC (e.g., the at least one RFIC 420) to transmit an RF signal corresponding to satellite communication to the first PA. The electronic device 101 may relatively reduce a risk of damage to at least one PA due to an overshoot that occurs in an operation of the plurality of modulators restoring the target voltage, based on a period associated with the level of a voltage input to the first PA.

In an embodiment, the electronic device 101 may activate the ground switch included in any one modulator of the first modulator or the second modulator for a second time after a first time from when the first signal starts to be input. The electronic device 101 may turn on the ground switch included in the first modulator or the second modulator after a configured time from when the RF signal corresponding to the satellite communication is input to the first PA. The electronic device 101 may allow a current charged in an inductor (e.g., the inductor 825a or the inductor 825b) to be transmitted to a ground, based on activating the ground switch for the configured time. The electronic device 101 may turn off the ground switch after the current charged in the inductor is transmitted to the ground. The electronic device 101 may allow the plurality of modulators to output a boosted voltage, based on maintaining the ground switch in a turned-off state during a time when the RF signal is not transmitted to the first PA. The electronic device 101 may relatively improve convenience in control, based on controlling only one modulator to activate the ground switch when performing a PA protection operation.

In an embodiment, the electronic device 101 may activate, based on the first period, the ground switch included in any one modulator of the first modulator or the second modulator for the second time within a third time before when the voltage input to the first PA is a maximum. In an embodiment, an IR drop in the voltage input to the first PA may periodically occur as the peak amplitude of the RF signal increases and/or decreases according to a certain period. The electronic device 101 may activate, based on a configured IR drop period, the ground switch included in the first modulator or the second modulator before an overshoot voltage in the first PA reaches a maximum. The electronic device 101 may relatively reduce a risk of damage to the at least one PA due to an overshoot or spike, based on transmitting the current charged in the inductor of the modulator to the ground according to the period of the RF signal input to the first PA.

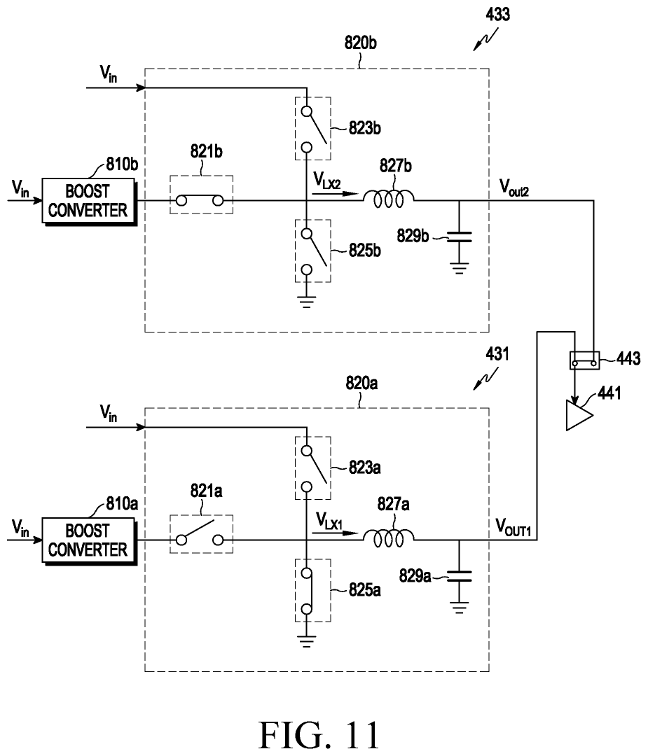

FIG. 11 is a circuit diagram illustrating an example of controlling a modulator of an electronic device according to various embodiments.

In an embodiment, referring to FIG. 11, the electronic device 101 may allow a relatively high current charged in an inductor 827a to be transmitted to a ground, based on controlling a ground switch 825a of a first modulator 431 to be activated, while power is supplied to a first PA 441, based on a second modulator 433.

Although FIG. 11 shows an example in which the ground switch 825a of the first modulator 431 is activated in an embodiment, those skilled in the art will understand that the electronic device 101 may allow a relatively high current charged in an inductor 827b to be transmitted to the ground, based on controlling a ground switch 825b of the second modulator 433 to be activated, while power is supplied to the first PA 441, based on the first modulator 431

In an embodiment, the electronic device 101 may relatively reduce a risk of damage to at least one PA, based on controlling a ground switch included in any one modulator of the first modulator 431 or the second modulator 433 for a configured time.

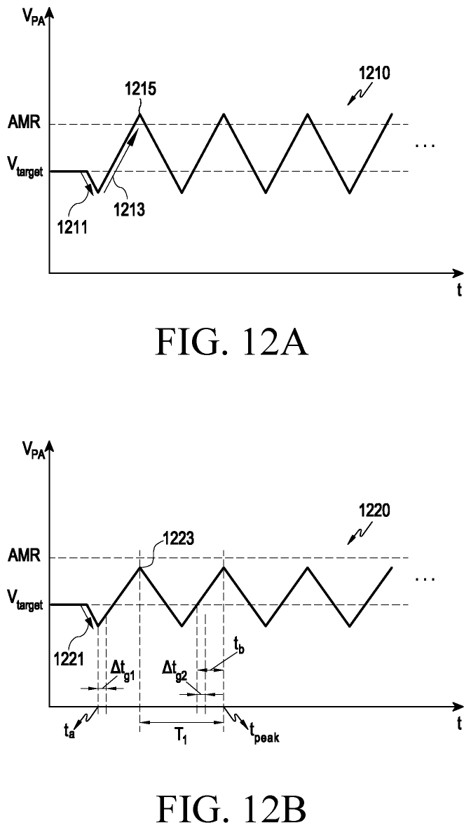

FIG. 12A is a graph 1210 illustrating an operation of an electronic device according to a comparative example for comparison with an embodiment.

According to the comparative example, the level of a voltage V_{PA} input to a PA (e.g., the first PA 441) may decrease (1211) due to an IR drop as described above. A modulator (e.g., the modulator 500 of FIG. 9) according to the comparative example may control a first switch (e.g., the first switch 521) and/or a second switch (e.g., the second switch 523) to restore a target voltage, based on detecting the IR drop. The modulator may increase (1213) the level of the voltage input to the PA, based on changing a duty cycle between an output voltage of a boost converter (e.g., the boost converter 510) and an output voltage of a battery (e.g., the battery 189). According to the comparative example, in an operation of restoring the target voltage, an overshoot voltage 1215 temporarily exceeding an AMR of the PA may occur, thus relatively increasing a risk of damage to the PA.

FIG. 12B is a graph 1220 illustrating an example operation of an electronic device according to various embodiments.

According to an embodiment, the level of a voltage V_{PA} input to a PA (e.g., the first PA 441) may decrease (1221) due to an IR drop as described above. In an embodiment, a modulator (e.g., the modulator 500 of FIG. 9) may control a first switch (e.g., the first switch 521) and/or a second switch (e.g., the second switch 523) to restore a target voltage, based on detecting the IR drop. The modulator may increase the level of the voltage input to the PA, based on changing a duty cycle between an output voltage of a boost converter (e.g., the boost converter 510) and an output voltage of a battery (e.g., the battery 189). In an embodiment, the electronic device 101 may activate a ground switch included in any one modulator of a first modulator or a second modulator while an RF signal associated with satellite communication is input to the PA supplied with power.

In an embodiment, the electronic device 101 may activate the ground switch included in any one modulator of the first modulator or the second modulator for a second time (e.g., Δt_{g1}) after a first time (e.g., ta) from when the RF signal starts to be input. A current charged in an inductor (e.g., the inductor 825a or the inductor 825b) may be transmitted to a ground, based on the ground switch being activated. The electronic device 101 may control, based on performing a PA protection operation, a peak value 1223 of the voltage input to the PA to be less than an AMR corresponding to the PA.

In an embodiment, the electronic device 101 may activate, based on a first period, the ground switch included in any one modulator of the first modulator or the second modulator for the second time within a third time before when the voltage input to the PA is a maximum. In an embodiment, the electronic device 101 may activate, based on a configured IR drop period T₁, the ground switch included in the first modulator or the second modulator for the second time before an overshoot voltage in the PA reaches a maximum. For example, the electronic device 101 may activate, based on the period T₁, the ground switch for the second time (e.g., Δt_{g2}) within the third time (e.g., tb) before when the voltage input to the PA is the maximum (e.g., tₚₑₐₖ). The electronic device 101 may relatively reduce a risk of damage to at least one PA due to an overshoot or spike, based on transmitting the current charged in the inductor of the modulator to the ground according to a period of the RF signal input to the PA.

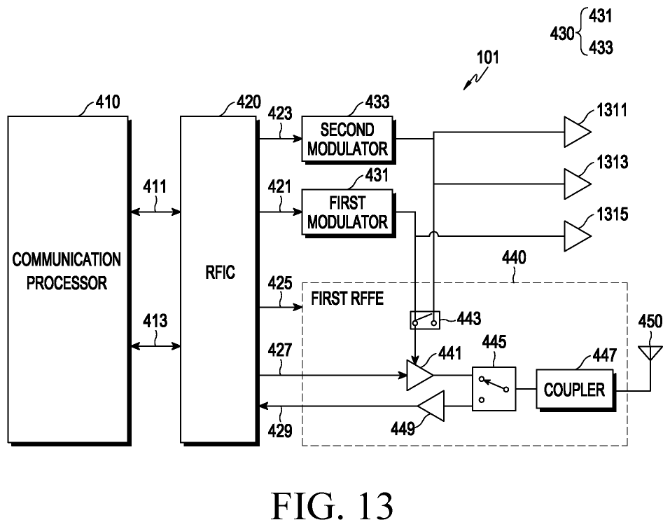

FIG. 13 is a block diagram illustrating an example configuration of an electronic device according to various embodiments.

In an embodiment, referring to FIG. 13, a first modulator 431 and/or a second modulator 433 may be electrically connected to at least one second PA 1311, 1313, and 1315. A redundant description of a component performing the same operation as that of a component illustrated in FIG. 4 among components illustrated in FIG. 13 may not be repeated.

In an embodiment, the at least one second PA 1311, 1313, and 1315 may be a PA included in an RFFE corresponding to a transmission/reception path of network communication requiring relatively low power. In an embodiment, the at least one second PA 1311, 1313, and 1315 may be turned off while a first PA 441 is turned on. In an embodiment, due to an electrical connection with the first modulator 431 and/or the second modulator 433, a high voltage may be applied even when the at least one second PA 1311, 1313, and 131 5 is turned off. For example, as described above, when an overshoot voltage exceeding an AMR of a PA occurs, a risk of damage to the at least one second PA 1311, 1313, and 1315 may relatively increase. The electronic device 101 according to an embodiment may control a maximum value of a voltage input to the at least one second PA 1311, 1313, and 1315 to be less than the AMR of the PA, based on activating a ground switch included in any one modulator of the first modulator 431 or the second modulator 433. The electronic device 101 may relatively reduce a risk of damage to the activated first PA 441 and the deactivated second PA 1311, 1313, and 1315, based on controlling the ground switch.

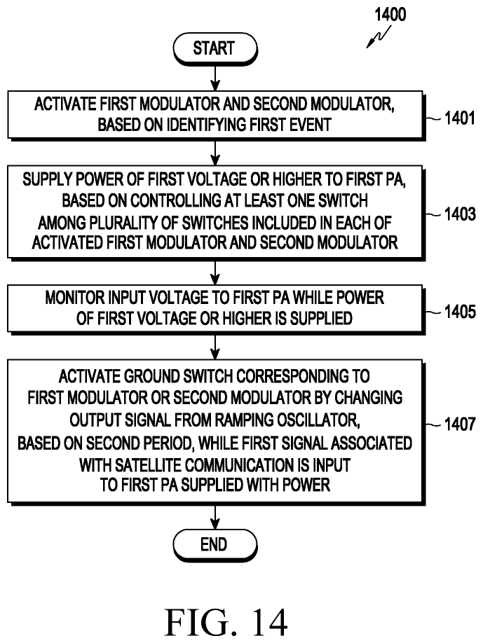

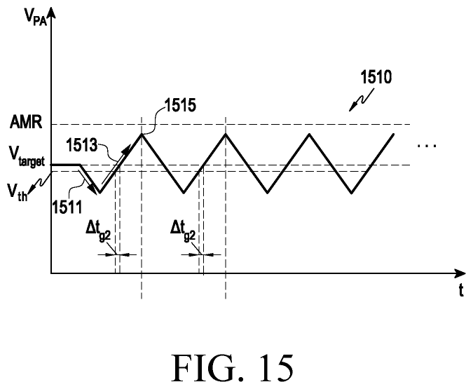

FIG. 14 is a flowchart 1400 illustrating an example method of operating an electronic device according to various embodiments.

According to an embodiment, in operation 1401, the electronic device 101 (e.g., the processor 120, the first communications processor 212, the second communications processor 214, the integrated communication processor 260, and/or the communications processor 410) may activate a first modulator (e.g., the first modulator 431) and a second modulator (e.g., the second modulator 433), based on identifying a first event. In an embodiment, since operation 1401 is at least partly the same as operation 1001, a description thereof overlapping with that of operation 1001 may not be repeated.

In an embodiment, based on activating the first modulator and the second modulator, the electronic device 101 may supply power of a first voltage or higher to a first PA (e.g., the first PA 441), based on controlling at least one switch among a plurality of switches included in each of the activated first modulator and second modulator (e.g., the first switch 821a of the first modulator, the second switch 823a of the first modulator, the ground switch 825a of the first modulator, the first switch 821b of the second modulator, the second switch 823b of the second modulator, and the ground switch 825b of the second modulator) in operation 1403. In an embodiment, since operation 1403 is at least partly the same as operation 1001, a description thereof overlapping with that of operation 1003 may not be repeated.

In an embodiment, the electronic device 101 (e.g., the first modulator 431 or the second modulator 433) may monitor an input voltage to the first PA, based on supplying the power of the first voltage or higher to the first PA (e.g., the first PA 441) in operation 1405. In an embodiment, the electronic device 101 (e.g., the modulator 500) may identify whether the voltage input to the first PA exceeds a configured threshold voltage or may identify whether a difference between a feedback voltage and a bandgap reference voltage is a threshold value or greater, based on identifying a current and/or a voltage detected by a feedback circuit (e.g., the feedback circuit 910). In an embodiment, the electronic device 101 (e.g., the modulator 500) may include an error amplifier, a comparator, and/or a ramping oscillator. In an embodiment, the input voltage to the first PA may be input to the error amplifier of the modulator through the feedback circuit. For example, an input to the error amplifier may be a bandgap reference voltage and a feedback voltage. An output from the error amplifier may be input to the comparator. The comparator may output a feedback signal, based on a difference between the bandgap reference voltage and the feedback voltage. The feedback signal output from the comparator may be input to the ramping oscillator. The state of at least one switch among a first switch (e.g., the first switch 521), a second switch (e.g., the second switch 523), and a ground switch 525 of a modulator (e.g., the first modulator 431 or the second modulator 433) may be changed based on a signal generated by the ramping oscillator. The electronic device 101 (e.g., the first modulator 431 or the second modulator 433) may activate the ground switch (e.g., the ground switch 825a or the ground switch 825b) corresponding to the modulator, based on changing an output signal from the ramping oscillator corresponding to the modulator, based on a period associated with the level of the voltage input to the first PA (e.g., the first PA 441). In an embodiment, while a first signal associated with satellite communication is input to the first PA supplied with the power, the electronic device 101 may change the output signal from the ramping oscillator corresponding to the modulator, based on a second period, thereby activating the ground switch corresponding to the first modulator (e.g., the first modulator 431) or the second modulator (e.g., the second modulator 433) in operation 1407. In an embodiment, the modulator (e.g., the first modulator 431 or the second modulator 433) may perform a step-up operation to restore a target voltage, based on identifying that a voltage drop (IR drop) occurs through the feedback circuit. In an embodiment, the modulator may activate the ground switch, based on controlling an output waveform of the ramping oscillator. For example, the first modulator 431 may activate the ground switch (e.g., the ground switch 825a) corresponding to the first modulator 431, based on controlling a ramping oscillator of the first modulator 431. The second modulator 433 may activate the ground switch (e.g., the ground switch 825a) corresponding to the second modulator 433, based on controlling a ramping oscillator of the second modulator 433. In an embodiment, as described above in operation 1405, the electronic device 101 (e.g., the first modulator 431 or the second modulator 433) may activate the ground switch (e.g., the ground switch 825a or the ground switch 825b) corresponding to the modulator, based on changing the output signal from the ramping oscillator corresponding to the modulator, based on the period associated with the level of the voltage input to the first PA (e.g., the first PA 441).

In an embodiment, the modulator may activate the ground switch for a configured time, based on a period configured by the electronic device 101 while inputting an RF signal to the first PA. The electronic device 101 may maintain an input voltage of a PA below a level at which damage to the PA may be caused, based on controlling a current charged in an inductor included in the modulator to be transmitted to a ground before an overshoot voltage exceeds an AMR of the PA. In an embodiment, the electronic device 101 may control the ground switch to be activated whenever identifying that the voltage input to the first PA exceeds the threshold voltage. The electronic device 101 may periodically control the ground switch to be activated in response to a time when the voltage input to the first PA reaches the threshold voltage, based on the period associated with the level of the voltage input to the first PA.

FIG. 15 is a graph 1510 illustrating an example operation of an electronic device according to various embodiments.

According to an embodiment, the level of a voltage V_{PA} input to a PA (e.g., the first PA 441) may decrease (1511) due to an IR drop as described above. In an embodiment, a modulator (e.g., the modulator 500 of FIG. 9) may control a first switch (e.g., the first switch 521) and/or a second switch (e.g., the second switch 523) to restore a target voltage, based on detecting the IR drop. The modulator may increase (1513) the level of the voltage input to the PA, based on changing a duty cycle between an output voltage of a boost converter (e.g., the boost converter 510) and an output voltage of a battery (e.g., the battery 189). In an embodiment, the electronic device 101 may activate a ground switch included in any one modulator of a first modulator or a second modulator while an RF signal associated with satellite communication is input to the PA supplied with power.

In an embodiment, the electronic device 101 may activate the ground switch included in any one modulator of the first modulator and the second modulator for a configured period (e.g., Δt_{g2}), based on identifying that the level of the voltage input to the first PA exceeds a threshold voltage Vₜₕ. A current charged in an inductor (e.g., the inductor 825a or the inductor 825b) may be transmitted to a ground, based on the ground switch being activated. The electronic device 101 may control a peak value 1515 of the voltage input to the PA to be less than an AMR corresponding to the PA, based on performing a PA protection operation. In an embodiment, the electronic device may periodically control the ground switch to be activated whenever identifying that the voltage input to the first PA exceeds the threshold voltage.

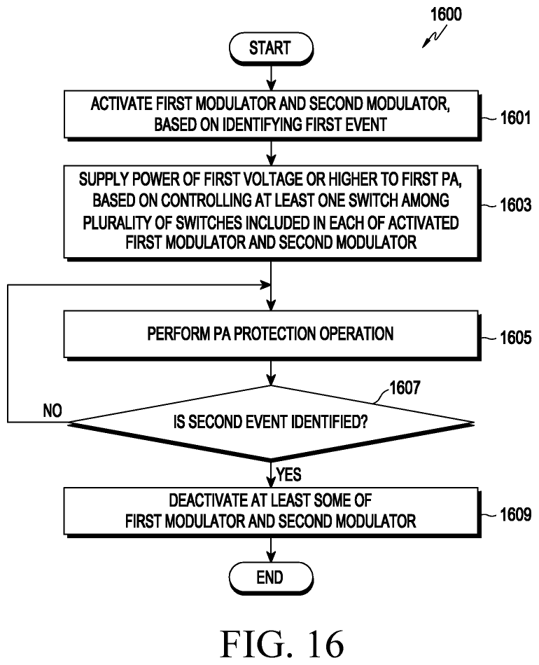

FIG. 16 is a flowchart 1600 illustrating an example method of operating an electronic device according to various embodiments.

According to an embodiment, in operation 1601, the electronic device 101 (e.g., the processor 120, the first communications processor 212, the second communications processor 214, the integrated communication processor 260, and/or the communications processor 410) may activate a first modulator (e.g., the first modulator 431) and a second modulator (e.g., the second modulator 433), based on identifying a first event. In an embodiment, operation 1601 is at least partly the same as operation 1001, a description thereof overlapping with that of operation 1001 may not be repeated.

In an embodiment, based on activating the first modulator and the second modulator, the electronic device 101 may supply power of a first voltage or higher to a first PA (e.g., the first PA 441), based on controlling at least one switch among a plurality of switches included in each of the activated first modulator and second modulator (e.g., the first switch 821a of the first modulator, the second switch 823a of the first modulator, the ground switch 825a of the first modulator, the first switch 821b of the second modulator, the second switch 823b of the second modulator, and the ground switch 825b of the second modulator) in operation 1603. In an embodiment, since operation 1603 is at least partly the same as operation 1003, a description thereof overlapping with that of operation 1003 may not be repeated.

In an embodiment, in operation 1605, the electronic device 101 may perform a PA protection operation, based on supplying power of a first voltage or higher to a first PA (e.g., the first PA 441). In an embodiment, operation 1605 may be at least partly the same as operation 1005. In an embodiment, operation 1605 may be at least partly the same as operation 1405 and operation 1407. Overlapping descriptions between operation 1605 and at least one of operation 1005, operation 1405, or operation 1407 may not be repeated.

In an embodiment, in operation 1607, the electronic device 101 may identify whether a second event occurs, based on performing the PA protection operation. In an embodiment, the second event may be a user input to terminate performance of satellite communication. In an embodiment, the second event may be an event associated with a communications network requiring lower power than that required to transmit and receive a signal to and from a satellite communications network. For example, the communication network requiring relatively low power may be a legacy network including a second-generation (2G), 3G, 4G, or long-term evolution (LTE) network, or a 5G network, and a specific communication network is not limited to the foregoing examples. In an embodiment, in operation 1605, the electronic device 101 may perform the PA protection operation, based on identifying that the second event does not occur (No in operation 1607).

In an embodiment, in operation 1609, the electronic device 101 may deactivate at least some of the first modulator and the second modulator, based on identifying the occurrence of the second event (Yes in operation 1607). The electronic device 101 may relatively reduce a risk of damage to the PA due to occurrence of an overshoot voltage, based on supplying power to the PA using only one modulator.

According to an example embodiment, an electronic device may include: memory 130 storing instructions, a first modulator, a second modulator, a first power amplifier (PA) electrically connected to the first modulator and the second modulator through a switch, and at least one processor, comprising processing circuitry, operatively connected to the first PA, the first modulator, and the second modulator. The instructions, when executed by at least one processor, individually and/or collectively, may cause the electronic device to: activate the first modulator and the second modulator, based on identifying a first event associated with satellite communication; supply power of a first voltage or higher to the first PA, based on controlling at least one switch among a plurality of switches included in each of the activated first modulator and second modulator; activate a ground switch connected to a ground, included in any one modulator of the first modulator or the second modulator, based on a first period, based on a first signal associated with the satellite communication being input to the first PA supplied with the power.

In an example embodiment, the instructions, when executed by at least one processor, individually and/or collectively, may cause the electronic device to activate the ground switch included in any one modulator of the first modulator or the second modulator for a second time after a first time from when the first signal starts to be input, as at least part of activating the ground switch connected to the ground included in any one modulator of the first modulator or the second modulator.

In an example embodiment, the instructions, when executed by at least one processor, individually and/or collectively, may cause the electronic device to activate, based on the first period, the ground switch included in any one modulator of the first modulator or the second modulator for a second time within a third time before based on a voltage input to the first PA being a maximum, as at least part of an operation of activating the ground switch connected to the ground included in any one modulator of the first modulator or the second modulator.

According to an example embodiment, an electronic device may include: memory storing instructions, a first modulator, a second modulator, a first power amplifier (PA) electrically connected to the first modulator and the second modulator through a switch, and at least one processor, comprising processing circuitry, operatively connected to the first PA, the first modulator, and the second modulator The instructions, when executed by at least one processor, individually and/or collectively, may cause the electronic device to activate the first modulator and the second modulator, based on identifying a first event associated with satellite communication. The instructions, when executed by at least one processor, may cause the electronic device to; supply power of a first voltage or higher to the first PA 441, based on controlling at least one switch among a plurality of switches included in each of the activated first modulator and second modulator. The instructions, when executed by the first modulator or the second modulator, may cause the electronic device to monitor an input voltage to the first PA based on the power of the first voltage or higher being supplied; and activate a ground switch connected to a ground corresponding to the first modulator or the second modulator by changing an output signal from a ramping oscillator, based on a second period, based on a first signal associated with the satellite communication being input to the first PA supplied with the power.

In an example embodiment, a level of an output voltage of the activated first modulator corresponds to a level of an output voltage of the second modulator based on the power being supplied to the first PA.

In an example embodiment, a first switch and a second switch among the plurality of switches included in each of the activated first modulator and second modulator may be selectively activated based on a first duty cycle based on the power being supplied to the first PA.

In an example embodiment, the instructions, when executed by at least one processor, individually and/or collectively, may cause the electronic device to deactivate at least some of the first modulator or the second modulator, based on identifying a second event associated with the satellite communication.

In an example embodiment, the electronic device may further include at least one second PA electrically connected to at least one of the first modulator or the second modulator.

The electronic device according to an embodiment may be one of various types of electronic devices. The electronic devices may include, for example, a portable communication device (e.g., a smartphone), a computer device, a portable multimedia device, a portable medical device, a camera, a wearable device, a home appliance, or the like. According to an embodiment of the disclosure, the electronic devices are not limited to those described above.

It should be appreciated that an embodiment of the present disclosure and the terms used therein are not intended to limit the technological features set forth herein to particular embodiments and include various changes, equivalents, or replacements for a corresponding embodiment. With regard to the description of the drawings, similar reference numerals may be used to refer to similar or related elements. It is to be understood that a singular form of a noun corresponding to an item may include one or more of the things, unless the relevant context clearly indicates otherwise. As used herein, each of such phrases as “A or B,” “at least one of A and B,” “at least one of A or B,” “A, B, or C,” “at least one of A, B, and C,” and “at least one of A, B, or C,” may include any one of, or all possible combinations of the items enumerated together in a corresponding one of the phrases. As used herein, such terms as “1st” and “2nd,” or “first” and “second” may be used to simply distinguish a corresponding component from another, and does not limit the components in other aspect (e.g., importance or order). It is to be understood that if an element (e.g., a first element) is referred to, with or without the term “operatively” or “communicatively”, as “coupled with,” “coupled to,” “connected with,” or “connected to” another element (e.g., a second element), the element may be coupled with the other element directly (e.g., wiredly), wirelessly, or via a third element.

As used in connection with an embodiment of the disclosure, the term “module” may include a unit implemented in hardware, software, or firmware, or any combination thereof, and may interchangeably be used with other terms, for example, “logic,” “logic block,” “part,” or “circuitry”. A module may be a single integral component, or a minimum unit or part thereof, adapted to perform one or more functions. For example, according to an embodiment, the module may be implemented in a form of an application-specific integrated circuit (ASIC).

An embodiment as set forth herein may be implemented as software (e.g., the program 140) including one or more instructions that are stored in a storage medium (e.g., internal memory 136 or external memory 138) that is readable by a machine (e.g., the electronic device 101). For example, a processor (e.g., the processor 120) of the machine (e.g., the electronic device 101) may invoke at least one of the one or more instructions stored in the storage medium, and execute it, with or without using one or more other components under the control of the processor. This allows the machine to be operated to perform at least one function according to the at least one instruction invoked. The one or more instructions may include a code generated by a compiler or a code executable by an interpreter. The machine-readable storage medium may be provided in the form of a non-transitory storage medium. Wherein, the “non-transitory” storage medium is a tangible device, and may not include a signal (e.g., an electromagnetic wave), but this term does not differentiate between where data is semi-permanently stored in the storage medium and where the data is temporarily stored in the storage medium.

According to an embodiment, a method according to an embodiment of the disclosure may be included and provided in a computer program product. The computer program product may be traded as a product between a seller and a buyer. The computer program product may be distributed in the form of a machine-readable storage medium (e.g., compact disc read only memory (CD-ROM)), or be distributed (e.g., downloaded or uploaded) online via an application store (e.g., PlayStore™), or between two user devices (e.g., smart phones) directly. If distributed online, at least part of the computer program product may be temporarily generated or at least temporarily stored in the machine-readable storage medium, such as memory of the manufacturer's server, a server of the application store, or a relay server.

According to an embodiment, each component (e.g., a module or a program) of the above-described components may include a single entity or multiple entities, and some of the multiple entities may be separately disposed in different components. According to an embodiment, one or more of the above-described components may be omitted, or one or more other components may be added. Alternatively or additionally, a plurality of components (e.g., modules or programs) may be integrated into a single component. In such a case, according to various embodiments, the integrated component may still perform one or more functions of each of the plurality of components in the same or similar manner as they are performed by a corresponding one of the plurality of components before the integration. According to an embodiment, operations performed by the module, the program, or another component may be carried out sequentially, in parallel, repeatedly, or heuristically, or one or more of the operations may be executed in a different order or omitted, or one or more other operations may be added.

While the disclosure has been illustrated and described with reference to various example embodiments, it will be understood that the various example embodiments are intended to be illustrative, not limiting. It will be further understood by those skilled in the art that various changes in form and detail may be made without departing from the true spirit and full scope of the disclosure, including the appended claims and their equivalents. It will also be understood that any of the embodiment(s) described herein may be used in conjunction with any other embodiment(s) described herein.

What is claimed is:

1. An electronic device comprising:
memory storing instructions;
a first modulator;
a second modulator;
a first power amplifier (PA) electrically connected to the first modulator and the second modulator through a switch; and
at least one processor, comprising processing circuitry, operatively connected to the memory, first PA, the first modulator, and the second modulator,
wherein the instructions, when executed by at least one processor, individually and/or collectively, cause the electronic device to:
activate the first modulator and the second modulator, based on identifying a first event associated with satellite communication;
supply power of a first voltage or higher to the first PA, based on controlling at least one switch among a plurality of switches included in each of the activated first modulator and second modulator; and
activate a ground switch connected to a ground included in any one of the first modulator or the second modulator, based on a first period, based on a first signal associated with the satellite communication being input to the first PA supplied with the power.

2. The electronic device of claim 1, wherein the instructions, when executed by at least one processor, individually and/or collectively, cause the electronic device to, as at least part of activating the ground switch connected to the ground included in any one of the first modulator or the second modulator, activate the ground switch included in any one of the first modulator or the second modulator for a second time after a first time from a time point at which the first signal starts to be input.

3. The electronic device of claim 1, wherein the instructions, when executed by at least one processor, individually and/or collectively, cause the electronic device to, as at least part of activating the ground switch connected to the ground included in any one of the first modulator or the second modulator:
activate, based on the first period, the ground switch included in any one of the first modulator or the second modulator for a second time within a third time from a time point at which a voltage input to the first PA reaches a maximum level.

4. The electronic device of claim 1, wherein a level of an output voltage of the activated first modulator corresponds to a level of an output voltage of the activated second modulator based on the power being supplied to the first PA.

5. The electronic device of claim 1, wherein a first switch and a second switch among the plurality of switches included in each of the activated first modulator and second modulator are selectively activated based on a first duty cycle based on the power being supplied to the first PA.

6. The electronic device of claim 1, further comprising at least one second PA electrically connected to at least one of the first modulator or the second modulator.

7. An electronic device comprising:
memory storing instructions;
a first modulator;
a second modulator;
a first power amplifier (PA) electrically connected to the first modulator and the second modulator through a switch; and
at least one processor, comprising processing circuitry, operatively connected to the memory, the first PA, the first modulator, and the second modulator,
wherein the instructions, when executed by at least one processor, individually and/or collectively, cause the electronic device to:
activate the first modulator and the second modulator, based on identifying a first event associated with satellite communication; and
supply power of a first voltage or higher to the first PA, based on controlling at least one switch among a plurality of switches included in each of the activated first modulator and second modulator, and
wherein the instructions, when executed by the first modulator or the second modulator, cause the electronic device to:
monitor an input voltage to the first PA based on the power of the first voltage or higher being supplied; and
activate a ground switch connected to a ground corresponding to the first modulator or the second modulator by changing an output signal from a ramping oscillator corresponding to the first modulator or the second modulator, based on a second period, based on a first signal associated with the satellite communication being input to the first PA supplied with the power.

8. The electronic device of claim 7, wherein the instructions, when executed by at least one processor, individually and/or collectively, cause the electronic device to deactivate at least one of the first modulator or the second modulator, based on identifying a second event associated with the satellite communication.

9. The electronic device of claim 7, wherein a level of an output voltage of the activated first modulator corresponds to a level of an output voltage of the activated second modulator based on the power being supplied to the first PA.

10. The electronic device of claim 7, wherein a first switch and a second switch among the plurality of switches included in each of the activated first modulator and second modulator are selectively activated based on a first duty cycle based on the power being supplied to the first PA.

11. The electronic device of claim 7, further comprising at least one second PA electrically connected to at least one of the first modulator or the second modulator.

12. A method of operating an electronic device comprising:
activating a first modulator of the electronic device and a second modulator of the electronic device, based on identifying a first event associated with satellite communication;
supplying power of a first voltage or higher to a first power amplifier (PA) of the electronic device electrically connected to the first modulator and the second modulator through a switch, based on controlling at least one switch among a plurality of switches included in each of the activated first modulator and second modulator; and
activating a ground switch connected to a ground included in any one of the first modulator or the second modulator, based on a first period, based on a first signal associated with the satellite communication being input to the first PA supplied with the power.

13. The method of claim 12, wherein the activating of the ground switch connected to the ground included in any one of the first modulator or the second modulator, comprises:
activating the ground switch included in any one of the first modulator or the second modulator for a second time after a first time from a time point at which the first signal starts to be input.

14. The method of claim 12, wherein the activating of the ground switch connected to the ground included in any one of the first modulator or the second modulator, comprises:
activating, based on the first period, the ground switch included in any one of the first modulator or the second modulator for a second time within a third time from a time point at which a voltage input to the first PA reaches a maximum level.

15. The method of claim 12, wherein a level of an output voltage of the activated first modulator corresponds to a level of an output voltage of the activated second modulator based on the power being supplied to the first PA.

16. The method of claim 12, wherein a first switch and a second switch among the plurality of switches included in each of the activated first modulator and second modulator are selectively activated based on a first duty cycle based on the power being supplied to the first PA.

17. A non-transitory storage medium storing computer-readable instructions that, when executed by at least one processor, individually and/or collectively, of an electronic device, cause the electronic device to perform at least one operation comprising:
activating a first modulator of the electronic device and a second modulator of the electronic device, based on identifying a first event associated with satellite communication;
supplying power of a first voltage or higher to a first power amplifier (PA) of the electronic device electrically connected to the first modulator and the second modulator through a switch, based on controlling at least one switch among a plurality of switches included in each of the activated first modulator and second modulator; and
activating a ground switch connected to a ground included in any one of the first modulator or the second modulator, based on a first period, based on a first signal associated with the satellite communication being input to the first PA supplied with the power.

18. The storage medium of claim 17, wherein the activating of the ground switch connected to the ground included in any one of the first modulator or the second modulator, comprises:
activating the ground switch included in any one of the first modulator or the second modulator for a second time after a first time from a time point at which the first signal starts to be input.

19. The storage medium of claim 17, wherein the activating of the ground switch connected to the ground included in any one of the first modulator or the second modulator, comprises:
activating, based on the first period, the ground switch included in any one of the first modulator or the second modulator for a second time within a third time from a time point at which a voltage input to the first PA reaches a maximum level.

20. The storage medium of claim 17, wherein a level of an output voltage of the activated first modulator corresponds to a level of an output voltage of the activated second modulator based on the power being supplied to the first PA.
